(19) United States
(12) Patent Application Publication
(10) Pub. No.: US 2023/0369542 A1
(43) Pub. Date: Nov. 16, 2023

(54) LIGHT-EMITTING DEVICE, MANUFACTURING METHOD FOR LIGHT-EMITTING DEVICE, AND DISPLAY APPARATUS

(71) Applicant: Samsung Display Co., LTD., Yongin-si, Gyeonggi-do (KR)

(72) Inventors: Hyun Min CHO, Seoul (KR); Dong Uk KIM, Hwaseong-si, Gyeonggi-do (KR); Se Young KIM, Gwangju (KR); Seung Geun LEE, Hwaseong-si, Gyeonggi-do (KR); Seung A LEE, Seoul (KR); Yo Han LEE, Hwaseong-Si, Gyeonggi-do (KR); Sung Ae JANG, Busan (KR); Hyung Rae CHA, Seoul (KR); Ji Hyun HAM, Asan-si, Chungcheongnam-do (KR)

(73) Assignee: Samsung Display Co., LTD., Yongin-si, Gyeonggi-do (KR)

(21) Appl. No.: 18/024,544

(22) PCT Filed: Dec. 16, 2020
(86) PCT No.: PCT/KR2020/018394

§ 371 Date: Mar. 3, 2023

(30) Foreign Application Priority Data
Sep. 7, 2020 (KR) 10-2020-0113657

(51) Int. Cl. H01L 33/44; H01L 25/16; H01L 33/00

(52) U.S. Cl. CPC H01L 33/44; H01L 25/167; H01L 33/0093; H01L 2933/0025

(57) ABSTRACT

A light-emitting device includes a light-emitting device core including a first semiconductor layer, a second semiconductor layer disposed on the first semiconductor layer, and an element active layer disposed between the first semiconductor layer and the second semiconductor layer; a first insulating layer disposed on the side surface of the light-emitting device core to surround the side surface of the light-emitting device core, and having first fixed charges; and a second insulating layer surrounding the outer side surface of the first insulating layer, and including a material having second fixed charges different from the first fixed charges.

### CROSS-REFERENCE TO RELATED APPLICATION

This application claims priority to and benefits of Korean Patent Application No. 10-2020-0113657 35 U.S.C. § 119, filed on Sep. 07, 2020 in the Korean Intellectual Property Office (KIPO), the entire contents of which are incorporated herein by reference.

### BACKGROUND

### 1. Technical Field

The disclosure relates to a provide a light-emitting device, a manufacturing method for the light-emitting device, and a display apparatus.

### 2. Description of the Related Art

Display devices have increasingly become of importance with the development of multimedia, and various types of display devices, such as an organic light-emitting diode (OLED) display device, a liquid crystal display (LCD) device, or the like, have been used.

A display device, which is a device for displaying an image, includes a display panel such as an OLED display panel or an LCD panel. The display panel may include light-emitting elements such as light-emitting diodes (LEDs), and the LEDs may be classified into OLEDs using an organic material as a light-emitting material and inorganic LEDs using an inorganic material as a light-emitting material.

### SUMMARY

Aspects of the disclosure provide a light-emitting element including a first insulating layer and a second insulating layer, which have different fixed charges from each other, on side surfaces of a first semiconductor layer, an element active layer, and a second semiconductor layer of the light-emitting element.

Aspects of the disclosure also provide a display device including the light-emitting element.

Aspects of the disclosure also provide a method of manufacturing a light-emitting element having improved film characteristics by forming the first insulating layer using a plasma enhanced atomic layer deposition method.

It should be noted that aspects of the disclosure are not limited thereto and other aspects, which are not mentioned herein, will be apparent to those of ordinary skill in the art from the following description.

According to an embodiment of the disclosure, a light-emitting element comprises a light-emitting element core comprising a first semiconductor layer, a second semiconductor layer disposed on the first semiconductor layer, and an element active layer disposed between the first semiconductor layer and the second semiconductor layer, a first insulating layer disposed on a side surface of the light-emitting element core to surround the side surface of the light-emitting element core and having a first fixed charge, and a second insulating layer surrounding an outer surface of the first insulating layer and containing a material having a second fixed charge different from the first fixed charge.

A polarity of the first fixed charge and a polarity of the second fixed charge may be identical to each other.

Each of the first and second fixed charges may be a positive fixed charge, and a magnitude of the first fixed charge may be smaller than a magnitude of the second fixed charge.

Each of the first and second fixed charges may be a negative fixed charge, and a magnitude of the first fixed charge may be greater than a magnitude of the second fixed charge.

A polarity of the first fixed charge and a polarity of the second fixed charge may be different from each other.

The first fixed charge may be a negative fixed charge, and the second fixed charge may be a positive fixed charge.

The first insulating layer may contain at least one of silicon oxide (SiOₓ), silicon nitride (SiNₓ), silicon oxynitride (SiOₓN_{y}), aluminum nitride (AlN), aluminum oxide (AlₓO_{y}), hafnium oxide (HfOₓ), and zirconium oxide (ZrOₓ), and the second insulating layer contains at least one of silicon oxide (SiOₓ), silicon nitride (SiNₓ), silicon oxynitride (SiOₓN_{y}), aluminum nitride (AlN), and aluminum oxide (AlₓO_{y}).

The first insulating layer may contain silicon oxide (SiOₓ), and the second insulating layer may contain aluminum oxide (AlₓO_{y}).

Each of the first fixed charge of the silicon oxide (SiOₓ) and the second fixed charge of the aluminum oxide (AlₓO_{y}) may be a positive fixed charge, and the first fixed charge may be smaller than the second fixed charge.

The first fixed charge of the silicon oxide (SiOₓ) may be a negative fixed charge, and the second fixed charge of the aluminum oxide (AlₓO_{y}) may be a positive fixed charge.

The first insulating layer may be disposed directly on side surfaces of the first semiconductor layer, the second semiconductor layer, and the element active layer.

According to an embodiment of the disclosure, a display device comprises a first electrode disposed on a substrate, a second electrode disposed on the substrate and spaced apart from the first electrode, and a light-emitting element disposed on the substrate and having both ends disposed on the first electrode and the second electrode, respectively, wherein the light-emitting element comprises a light-emitting element core comprising a first semiconductor layer, a second semiconductor layer disposed on the first semiconductor layer, and an element active layer disposed between the first semiconductor layer and the second semiconductor layer, a first insulating layer disposed on a side surface of the light-emitting element core to surround the side surface of the light-emitting element core and having a first fixed charge, and a second insulating layer surrounding an outer surface of the first insulating layer and containing a material having a second fixed charge different from the first fixed charge.

A polarity of the first fixed charge and a polarity of the second fixed charge may be identical to each other.

Each of the first and second fixed charges may be a positive fixed charge, and a magnitude of the first fixed charge may be smaller than a magnitude of the second fixed charge.

Each of the first and second fixed charges may be a negative fixed charge, and a magnitude of the first fixed charge may be greater than a magnitude of the second fixed charge.

A polarity of the first fixed charge and a polarity of the second fixed charge may be different from each other.

The first fixed charge may be a negative fixed charge, and the second fixed charge may be a positive fixed charge.

The display device may further comprise a first insulating layer disposed on the light-emitting element to expose both ends of the light-emitting element, a first contact electrode disposed on the first electrode and electrically contacting an end of the light-emitting element exposed by the first electrode and the first insulating layer, and a second contact electrode disposed on the second electrode and electrically contacting another end of the light-emitting element exposed by the second electrode and the first insulating layer.

A thickness of the second insulating layer which is exposed by the first insulating layer may be smaller than a thickness of the second insulating layer which is not exposed by the first insulating layer.

At both ends of the light-emitting element, the second insulating layer may expose a part of the first insulating layer.

According to an embodiment of the disclosure, a method of manufacturing a light-emitting element, comprises forming a core structure on one surface of a base substrate, forming a first insulating material layer containing a material having a first fixed charge on an outer surface of the core structure using plasma atomic layer deposition (PEALD), forming a second insulating material layer containing a material having a second fixed charge different from the first fixed charge on one surface of the first insulating material layer, forming an element rod by partially removing the first insulating material layer and the second insulating material layer to expose a top surface of the core structure, and separating the element rod from the base substrate.

The forming of the first insulating material layer may comprise providing a precursor onto the core structure, providing a reactive gas onto the core structure, and generating plasma of the reactive gas on the core structure.

The first insulating material layer may contain silicon oxide (SiOₓ), the second insulating material layer may contain aluminum oxide (AlₓO_{y}), the precursor may comprise a silicon-containing precursor, and the reactive gas may contain an oxygen gas.

The forming of the core structure may comprise forming a first stacked structure comprising a first semiconductor material layer on the base substrate, an element active material layer on the first semiconductor material layer, and a second semiconductor material layer on the element active material layer, and vertically etching the first stacked structure in a direction perpendicular to a top surface of the base substrate.

The details of other embodiments are included in the detailed description and the accompanying drawings.

In accordance with the light-emitting element according to one embodiment, since the first insulating layer and the second insulating layer of the light-emitting element include materials having different fixed charges from each other, it is possible to improve luminance deterioration of the light-emitting element. In addition, since the second insulating layer, which includes a material having different fixed charges from those of the material of the first insulating layer, is disposed to surround the first insulating layer, the second insulating layer may protect the first insulating layer, and thus a light-emitting element with high reliability may be provided.

In addition, in accordance with the method of manufacturing the light-emitting element according to one embodiment, a deposition process for forming the first insulating layer of the light-emitting element may be performed using plasma enhanced atomic layer deposition (PEALD). The first insulating layer formed by plasma enhanced atomic layer deposition (PEALD) may have an improved film property compared to a first insulating layer formed by thermal atomic layer deposition (thermal ALD). Accordingly, by forming the first insulating layer using plasma enhanced atomic layer deposition (PEALD), it is possible to provide a light-emitting element with high reliability.

The effects according to the embodiments are not limited by the contents exemplified above, and more various effects are included in this disclosure.

### BRIEF DESCRIPTION OF THE DRAWINGS

FIG. 1 is a schematic plan view of a display device according to an embodiment.

FIG. 2 is a schematic plan view of a pixel of a display device according to an embodiment.

FIG. 3 is a schematic cross-sectional view taken along lines Qa-Qa′, Qb-Qb′, and Qc-Qc′ of FIG. 2.

FIG. 4 is a schematic perspective view of a light-emitting element according to an embodiment.

FIG. 5 is a schematic cross-sectional view taken along line V-V′ of FIG. 4.

FIG. 6 is a schematic enlarged view illustrating an example of part Q of FIG. 3.

FIG. 7 is a schematic flowchart showing a method of manufacturing a light-emitting element according to an embodiment.

FIGS. 8 to 14 are schematic cross-sectional views illustrating the manufacturing process of a light-emitting element according to an embodiment.

FIG. 15 is a graph that compares light emission characteristics of light-emitting elements according to first insulating layers formed by plasma enhanced atomic layer deposition (PEALD) and thermal atomic layer deposition (thermal ALD), respectively, when the first insulating layers include silicon oxide (SiOx).

FIG. 16 is a schematic enlarged view illustrating another example of part Q of FIG. 3.

FIG. 17 is a schematic enlarged view illustrating still another example of part Q of FIG. 3.

FIG. 18 is a schematic enlarged view illustrating still another example of part Q of FIG. 3.

FIG. 19 is a schematic cross-sectional view of a light-emitting element according to another embodiment.

FIG. 20 is a schematic cross-sectional view of a light-emitting element according to still another embodiment.

FIG. 21 is a schematic cross-sectional view of a light-emitting element according to still another embodiment.

### DETAILED DESCRIPTION OF THE EMBODIMENTS

Advantages and features of the disclosure and methods of accomplishing the same may be understood more readily by reference to the following detailed description of embodiments and the accompanying drawings. However, the disclosure is not limited to the embodiments disclosed below, but may be implemented in other forms. That is, the disclosure will only be defined by the appended claims.

It will also be understood that when a layer is referred to as being “on” another layer or substrate, it can be directly on the other layer or substrate, or intervening layers may also be present. In contrast, when an element is referred to as being “directly on” another element, there are no intervening elements present.

The same reference numbers indicate the same components throughout the specification.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure will be described with reference to the drawings.

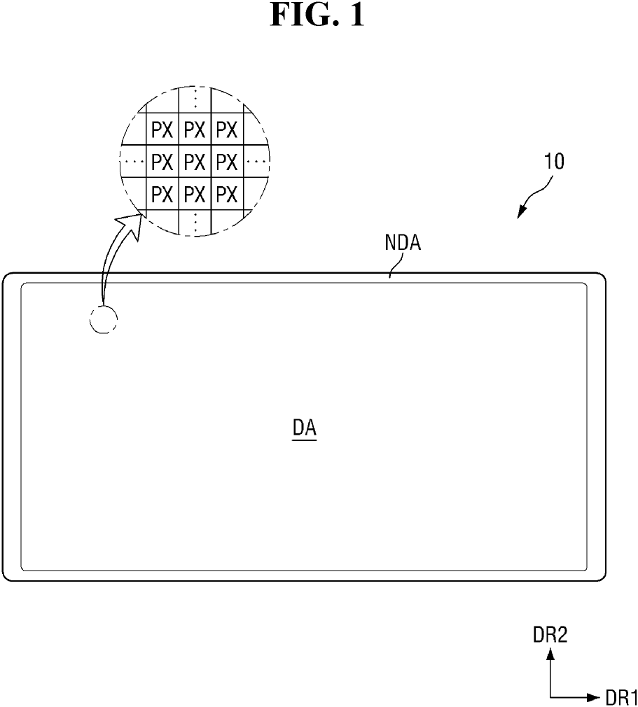

FIG. 1 is a schematic plan view of a display device according to an embodiment.

Referring to FIG. 1, a display device 10 displays a moving image or a still image. The display device 10 may refer to any electronic device providing a display screen. Examples of the display device 10 may include a television, a laptop computer, a monitor, a billboard, an Internet of things (IoT) device, a mobile phone, a smartphone, a tablet personal computer (PC), an electronic watch, a smartwatch, a watch phone, a head-mounted display, a mobile communication terminal, an electronic notebook, an e-book reader, a portable multimedia player (PMP), a navigation device, a game machine, a digital camera, a camcorder and the like, which provide a display screen.

The display device 10 includes a display panel which provides a display screen. Examples of the display panel may include an inorganic light-emitting diode display panel, an organic light-emitting display panel, a quantum dot light-emitting display panel, a plasma display panel and a field emission display panel. In the following description, a case where an inorganic light-emitting diode display panel is applied as a display panel will be exemplified, but the disclosure is not limited thereto, and other display panels may be applied within the same scope of technical spirit.

Hereinafter, a first direction DR1, a second direction DR2, and a third direction DR3 may be defined in drawings of an embodiment describing the display device 10. The first direction DR1 and the second direction DR2 may be directions perpendicular to each other in a plane. The third direction DR3 may be a direction perpendicular to a plane on which the first direction DR1 and the second direction DR2 may be located. The third direction DR3 may be perpendicular to each of the first direction DR1 and the second direction DR2. In the embodiment describing the display device 10, the third direction DR3 indicates a thickness direction of the display device 10.

The display device 10 may have a rectangular shape including long and short sides such that the side in the first direction DR1 is longer than the side in the second direction DR2 in plan view. A corner portion where the long side and the short side of the display device 10 meet each other may be right-angled in plan view. However, the disclosure is not limited thereto, and it may be rounded to have a curved shape. The planar shape of the display device 10 is not limited to the illustrated example, and may be other shapes such as a square shape, a quadrilateral shape with rounded corners (vertices), other polygonal shapes and a circular shape.

A display surface of the display device 10 may be disposed on a side of the third direction DR3 which is the thickness direction. In embodiments describing the display device 10, unless otherwise noted, the term “upward” refers to a side of the third direction DR3, which is the display direction, and the term “top surface” refers to a surface toward the a side of the third direction DR3. Further, the term “downward” refers to the other side of the third direction DR3, which is an opposite direction to the display direction, and the term “bottom surface” refers to a surface toward the other side of the third direction DR3. Furthermore, “left”, “right”, “upper” and “lower” indicate directions when the display device 10 is viewed from above. For example, “right side” indicates a side of the first direction DR1, “left side” indicates the other side of the first direction DR1, “upper side” indicates a side of the second direction DR2, and “lower side” indicates the other side of the second direction DR2.

The display device 10 may include a display area DA and a non-display area NDA. The display area DA may be an area where an image can be displayed, and the non-display area NDA may be an area where an image is not displayed.

The shape of the display area DA may follow the shape of the display device 10. For example, the shape of the display area DA may have a rectangular shape similar to the overall shape of the display device 10 in plan view. The display area DA may substantially occupy the center of the display device 10.

The display area DA may include pixels PX. The pixels PX may be arranged in a matrix. The shape of each pixel PX may be a rectangular or square shape in plan view. However, the shape of each pixel PX is not limited thereto, and may be a rhombic shape in which each side is inclined with respect to a direction. The pixels PX may be alternately disposed in a stripe type or a PenTile® type.

The non-display area NDA may be disposed around the display area DA. The non-display area NDA may completely or partially surround the display area DA. In an embodiment, the display area DA may have a rectangular shape, and the non-display area NDA may be disposed adjacent to four sides of the display area DA. The non-display area NDA may form a bezel of the display device 10. In the non-display area NDA, wires and circuit drivers belonging to the display device 10, or pad portions on which an external device is mounted may be disposed.

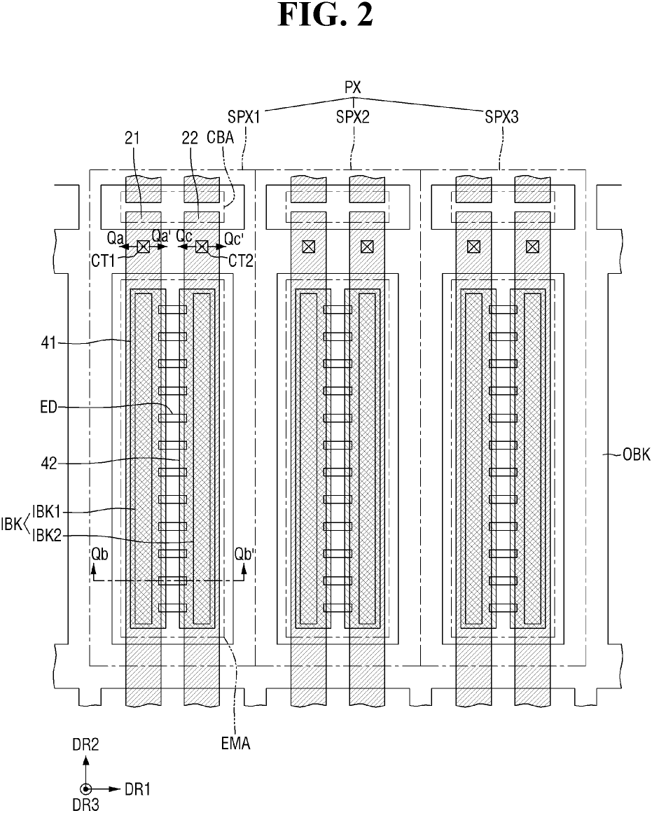

FIG. 2 is a schematic plan view of a pixel of a display device according to an embodiment.

Referring to FIG. 2, each pixel PX may include sub-pixels SPX (SPX1, SPX2, and SPX3). For example, a pixel PX may include a first sub-pixel SPX1, a second sub-pixel SPX2, and a third sub-pixel SPX3. The first sub-pixel SPX1 may emit light of a first color, the second sub-pixel SPX2 may emit light of a second color, and the third sub-pixel SPX3 may emit light of a third color. The first color may be blue, the second color may be green, and the third color may be red. However, the disclosure is not limited thereto, and the sub-pixels SPX1, SPX2, and SPX3 may emit light of a same color. FIG. 2 illustrates that a pixel PX includes three sub-pixels SPX1, SPX2, and SPX3, but the disclosure is not limited thereto, and each pixel PX may include a larger number of sub-pixels SPX.

Each sub-pixel SPXn of the display device 10 may include an emission area EMA and a non-emission area (not shown), where ‘n’ may be a natural number. The emission area EMA may be an area where the light emitted from a light-emitting element ED is emitted, and the non-emission area may be an area where no light is emitted because the light emitted from the light-emitting element ED does not reach the area.

The emission area EMA may include an area in which the light-emitting element ED is disposed and an area adjacent thereto. The emission area EMA may further include a region in which the light emitted from the light-emitting element ED is reflected or refracted by another member and emitted.

Each sub-pixel SPX may further include a first region CBA disposed in the non-emission area. The first region CBA may be disposed at a side of the emission area EMA in the second direction DR2 (e.g., an upper side in FIG. 2). The first region CBA may be disposed between the emission areas EMA of the sub-pixels SPX disposed adjacent to each other in the second direction DR2.

The emission areas EMA of the respective sub-pixels SPX included in a pixel PX may be arranged to be spaced apart from each other in the first direction DR1. Similarly, the first regions CBA of the respective sub-pixels SPX included in a pixel PX may be arranged to be spaced apart from each other in the first direction DR1. The emission areas EMA and the first regions CBA each may be arranged to be spaced apart from each other in the first direction DR1, while the emission area EMA and the first region CBA may be arranged alternately in the second direction DR2.

The first region CBA may be a region in which electrodes 21 and 22, which will be described below, may be separated from each other. Each of the sub-pixels SPX, which may be adjacent to each other in the second direction DR2, may include the first and second electrodes 21 and 22 that extend in the second direction DR2. The first and second electrodes 21 and 22 may be separated from each other in the first region CBA. Accordingly, parts of the first and second electrodes 21 and 22, which may be disposed in each sub-pixel SPX, may be disposed in the first region CBA. The arrangement of the first and second electrodes 21 and 22 will be described below in detail.

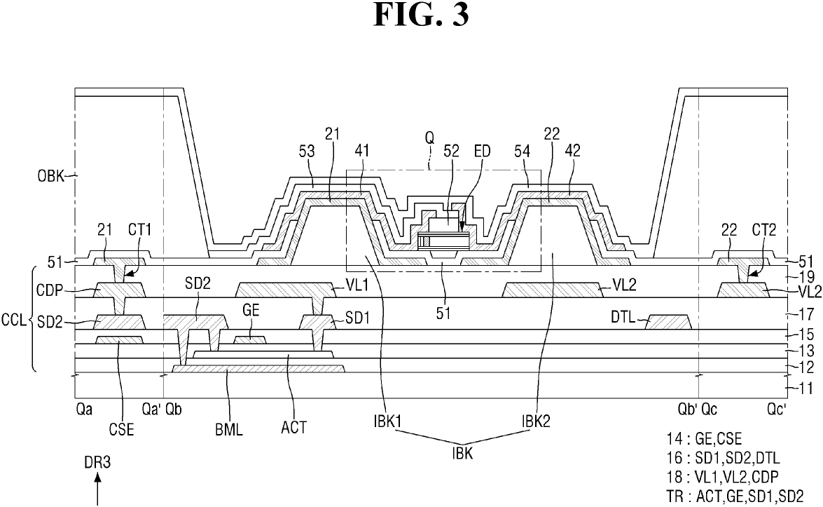

FIG. 3 is a schematic cross-sectional view taken along lines Qa-Qa′, Qb-Qb′, and Qc-Qc′ of FIG. 2.

Referring to FIG. 3, the display device 10 may include a first substrate 11, a circuit element layer CCL disposed on the first substrate 11, and a light-emitting element layer disposed on the circuit element layer CCL. Hereinafter, a cross-sectional structure of the circuit element layer CCL of the display device 10 will be described with reference to FIG. 3.

The first substrate 11 may be an insulating substrate. The first substrate 11 may be made of an insulating material such as glass, quartz, or polymer resin. Further, the first substrate 11 may be a rigid substrate, but may be a flexible substrate which can be bent, folded or rolled.

A lower metal layer BML may be disposed on the first substrate 11. The lower metal layer BML may be a light blocking layer that serves to protect an active material layer (or active layer) ACT of a transistor TR from external light. The lower metal layer BML may include a material for blocking light. For example, the lower metal layer BML may be formed of an opaque metal material that blocks transmission of light.

The lower metal layer BML has a patterned shape. The lower metal layer BML may be disposed to cover at least a channel region of an active material layer (or active layer) ACT of the transistor TR from the bottom, and may be further disposed to cover the entire active material layer ACT of the transistor TR from the bottom. However, the disclosure is not limited thereto, and the lower metal layer BML may be omitted.

A buffer layer 12 may be disposed on the lower metal layer BML. The buffer layer 12 may be disposed to cover (or overlap) the entire surface of the first substrate 11 where the lower metal layer BML is disposed. The buffer layer 12 may serve to protect the transistor TR from moisture permeating through the first substrate 11 that is susceptible to moisture permeation. The buffer layer 12 may be formed as inorganic layers that may be alternately stacked each other. For example, the buffer layer 12 may be formed as a multilayer in which inorganic layers including at least one of silicon oxide (SiOₓ), silicon nitride (SiNₓ) or silicon oxynitride (SiON) may be alternately stacked each other.

The semiconductor layer may be disposed on the buffer layer 12. The semiconductor layer may include the active material layer ACT of the transistor TR. The active material layer ACT may be disposed to overlap the lower metal layer BML.

Although FIG. 3 illustrates only a transistor TR of the transistors included in a sub-pixel SPX of the display device 10, the disclosure is not limited thereto. For example, each sub-pixel SPX of the display device 10 may include a larger number of transistors. For example, the display device 10 may include two or three transistors for each sub-pixel SPX.

The semiconductor layer may include polycrystalline silicon, monocrystalline silicon, oxide semiconductor, and the like.

In an embodiment, in case that the semiconductor layer contains polycrystalline silicon, the polycrystalline silicon may be formed by crystallizing amorphous silicon. In case that the semiconductor layer contains polycrystalline silicon, the active material layer ACT may include doping regions doped with impurities and channel regions disposed therebetween. In another embodiment, the semiconductor layer may contain an oxide semiconductor. The oxide semiconductor may be, for example, indium tin oxide (ITO), indium zinc oxide (IZO), indium gallium oxide (IGO), indium zinc tin oxide (IZTO), indium gallium zinc oxide (IGZO), indium gallium tin oxide (IGTO), indium gallium zinc tin oxide (IGZTO) or the like.

A gate insulating layer 13 may be disposed on the semiconductor layer. The gate insulating layer 13 may function as a gate insulating layer of the transistor TR. The gate insulating layer 13 may be formed as an inorganic layer including an inorganic material, such as silicon oxide (SiOₓ), silicon nitride (SiNₓ) or silicon oxynitride (SiON), or a stacked structure thereof.

A first conductive layer 14 may be disposed on the gate insulating layer 13. The first conductive layer 14 may include a gate electrode GE of the transistor TR and a first capacitance electrode CSE of a storage capacitor.

The gate electrode GE may be disposed to overlap the channel region of the active material layer ACT in the third direction DR3. The first capacitance electrode CSE may be disposed to overlap a second source/drain electrode SD2 of the transistor TR, which will be described below, in the third direction DR3. Since the first capacitance electrode CSE is disposed to overlap the second source/drain electrode SD2 in the third direction DR3, a storage capacitor may be formed therebetween. In some embodiments, the first capacitance electrode CSE and the gate electrode GE may be integrated into a layer. A part of the integrated layer may include the gate electrode GE, and another part thereof may include the first capacitance electrode CSE.

The first conductive layer 14 may be formed as a single layer or multiple layers made of at least one of molybdenum (Mo), aluminum (Al), chromium (Cr), gold (Au), titanium (Ti), nickel (Ni), neodymium (Nd) and copper (Cu) or an alloy thereof. However, the disclosure is not limited thereto.

An interlayer insulating layer 15 may be disposed on the first conductive layer 14. The interlayer insulating layer 15 may be disposed to cover the first conductive layer 14. The interlayer insulating layer 15 may include an inorganic insulating material such as silicon oxide (SiOₓ), silicon nitride (SiNₓ), and silicon oxynitride (SiON).

A second conductive layer 16 may be disposed on the interlayer insulating layer 15. The second conductive layer 16 may include a first source/drain electrode SD1 and a second source/drain electrode SD2 of the first transistor TR, and a data line DTL.

The first and second source/drain electrodes SD1 and SD2 may be electrically connected to both end areas (e.g., each doping region of the active material layer ACT of the transistor TR) of the active material layer ACT of the transistor TR, respectively, through contact holes penetrating the interlayer insulating layer 15 and the gate insulating layer 13. The second source/drain electrode SD2 of the transistor TR may be electrically connected to the lower metal layer BML through another contact hole penetrating the interlayer insulating layer 15, the gate insulating layer 13, and the buffer layer 12.

The data line DTL may apply a data signal to another transistor (not shown) included in the display device 10. Although not shown in the drawing, the data line DTL may be connected to source/drain electrodes of other transistors.

The second conductive layer 16 may be formed as a single layer or multiple layers made of at least one of molybdenum (Mo), aluminum (Al), chromium (Cr), gold (Au), titanium (Ti), nickel (Ni), neodymium (Nd) and copper (Cu) or an alloy thereof. However, the disclosure is not limited thereto.

A passivation layer 17 may be disposed on the second conductive layer 16. The passivation layer 17 serves to cover and protect the second conductive layer 16. The passivation layer 17 may include an inorganic insulating material such as silicon oxide (SiOₓ), silicon nitride (SiNₓ), and silicon oxynitride (SiON).

A third conductive layer 18 may be disposed on the passivation layer 17. The third conductive layer 18 may include a first power line VL1, a second power line VL2, and a first conductive pattern CDP.

A high-potential voltage (or a first source voltage) may be supplied to the first power line VL1, and a low-potential voltage (or a second source voltage) lower than the high-potential voltage supplied to the first power line VL1 may be supplied to the second power line VL2. The second power line VL2 may be electrically connected to a second electrode 22 to supply the low-potential voltage (the second source voltage) to the second electrode 22. Further, an alignment signal for aligning the light-emitting element ED may be applied to the second power line VL2 during the manufacturing process of the display device 10.

The first conductive pattern CDP may be electrically connected to the second source/drain electrode SD2 of the transistor TR through a contact hole penetrating the passivation layer 17. The first conductive pattern CDP may be electrically connected to the first electrode 21 through a first contact hole CT1 to be described below to transmit the first source voltage applied from the first power line VL1 to the first electrode 21.

The third conductive layer 18 may be formed as a single layer or multiple layers made of at least one of molybdenum (Mo), aluminum (Al), chromium (Cr), gold (Au), titanium (Ti), nickel (Ni), neodymium (Nd) and copper (Cu) or an alloy thereof. However, the disclosure is not limited thereto.

A via layer 19 may be disposed on the third conductive layer 18. The via layer 19 may be disposed on the passivation layer 17 on which the third conductive layer 18 is disposed. The via layer 19 may serve to planarize the surface. The via layer 19 may include an organic insulating material, for example, an organic material such as polyimide (PI).

Hereinafter, a structure of the light-emitting element layer disposed on the via layer 19 will be described in detail with reference to FIGS. 2 and 3.

The light-emitting element layer may be disposed on the via layer 19 of the circuit element layer CCL. The light-emitting element layer may include the light-emitting elements ED, a first bank IBK, a second bank OBK, the first and second electrodes 21 and 22, first and second contact electrodes 41 and 42, and insulating layers 51, 52, 53, and 54.

The first bank IBK may be disposed on the via layer 19. The first bank IBK may have a shape extending in the second direction DR2 within each sub-pixel SPX in plan view. The first bank IBK may end while being separated within the emission area EMA partitioned by the second bank OBK so that the first bank IBK does not extend to the adjacent sub-pixel SPX in the second direction DR2.

The first bank IBK may include a first sub-bank IBK1 and a second sub-bank IBK2. The first sub-bank IBK1 and the second sub-bank IBK2 may face and be spaced apart from each other in the first direction DR1. For example, the first sub-bank IBK1 may be disposed on a left side of the emission area EMA in plan view, and the second sub-bank IBK2 may be disposed on a right side of the emission area EMA in plan view. The separation space formed between the first sub-bank IBK1 and the second sub-bank IBK2 spaced apart from each other may provide an area where the light-emitting elements EDs may be disposed.

The first bank IBK (IBK1 and IBK2) may have a structure in which at least a part of the first bank IBK protrudes upward (e.g., a side in the third direction DR3) with respect to the top surface of the via layer 19. The protruding part of the first bank IBK may have an inclined side surface.

The first bank IBK may serve to change the traveling direction of the light emitted from the light-emitting element ED toward the inclined side surface of the first bank IBK to an upward direction (e.g., a display direction). In other words, the first bank IBK may serve as a reflective partition wall that provides a space where the light-emitting element ED is disposed and changes the traveling direction of the light emitted from the light-emitting element ED to the display direction.

On the other hand, although FIG. 3 illustrates that the side surface of the first bank IBK may be inclined in a linear shape, the disclosure is not limited thereto. For example, the side surface (or outer surface) of the first bank IBK may have a curved semicircular or semi-elliptical shape. In an embodiment, the first bank IBK may include an organic insulating material such as polyimide (PI), but is not limited thereto.

The first electrode 21 and the second electrode 22 may be disposed on the first bank IBK and the via layer 19 exposed by the first bank IBK. Specifically, the first electrode 21 may be disposed on the first sub-bank IBK1 and the second electrode 22 may be disposed on the second sub-bank IBK2.

Each of the first electrode 21 and the second electrode 22 may have a shape extending in the second direction DR2 in plan view. The first electrode 21 and the second electrode 22 may be spaced apart from each other and disposed to face each other in the first direction DR1. In plan view, the shapes of the first electrode 21 and the second electrode 22 may be substantially similar to the shapes of the first sub-bank IBK1 and the second sub-bank IBK2, respectively, but the areas of the first electrode 21 and the second electrode 22 may be greater than those of the first sub-bank IBK1 and the second sub-bank IBK2, respectively.

The first electrode 21 may extend in the second direction DR2 in plan view so as to overlap a part of the second bank OBK extending in the first direction DR1. The first electrode 21 may contact the first conductive pattern CDP through the first contact hole CT1 passing through the via layer 19. The first electrode 21 may be electrically connected to the transistor TR through the first conductive pattern CDP.

The second electrode 22 may extend in the second direction DR2 in plan view so as to overlap a part of the second bank OBK extending in the first direction DR1. The second electrode 22 may contact the second power line VL2 through a second contact hole CT2 penetrating the via layer 19.

Although FIG. 3 illustrates that the first contact hole CT1 and the second contact hole CT2 overlap the second bank OBK, the disclosure is not limited thereto. For example, the first contact hole CT1 and the second contact hole CT2 may be disposed in the emission area EMA surrounded by the second bank OBK so as not to overlap the second bank OBK.

The first and second electrodes 21 and 22 may be respectively separated from other electrodes 21 and 22, which may be included in the sub-pixel SPX adjacent to each sub-pixel SPX in the second direction DR2, in the first region CBA of the sub-pixel SPX. Such shapes of the first electrode 21 and the second electrode 22 may be formed in a process of electrically disconnecting the electrodes 21 and 22 in the first region CBA after a process of arranging the light-emitting elements ED during the manufacturing process of the display device 10. However, the disclosure is not limited thereto. In some embodiments, each of the first and second electrodes 21 and 22 may extend to the sub-pixels SPX adjacent to each other in the second direction DR2 to be continuously disposed, or only one of the first and second electrodes 21 and 22 may be divided.

The shapes and arrangement of the first electrode 21 and the second electrode 22 arranged in each sub-pixel SPX are not particularly limited as long as at least parts of the first electrode 21 and the second electrode 22 may be spaced apart from each other to form a space in which the light-emitting element ED may be disposed. FIGS. 2 and 3 illustrate that a first electrode 21 and a second electrode 22 may be disposed for each sub-pixel SPX, but the disclosure is not limited thereto, and a larger number of the first electrodes 21 and a larger number of the second electrodes 122 may be disposed in the sub-pixel SPX. The planar shape of the first electrode 21 and the second electrode 22 disposed in each sub-pixel SPX is not limited to a shape extending in a direction, and may be partially curved or bent. Also, an electrode thereof may be disposed to surround the other electrode.

The first electrode 21 may be disposed on the first sub-bank IBK1 to cover the outer surface of the first sub-bank IBK1. The first electrode 21 may extend outward from the side surface of the first sub-bank IBK1 to be disposed on a part of the top surface of the via layer 19 that may be exposed by the first sub-bank IBK1 and the second sub-bank IBK2 in the area between the first sub-bank IBK1 and the second sub-bank IBK2.

The second electrode 22 may be disposed on the second sub-bank IBK2 to cover the outer surface of the second sub-bank IBK2. The second electrode 22 may extend outward from the side surface of the second sub-bank IBK2 to be disposed on a part of the top surface of the via layer 19 that may be exposed by the first sub-bank IBK1 and the second sub-bank IBK2 in the area between the first sub-bank IBK1 and the second sub-bank IBK2. The first electrode 21 and the second electrode 22 may be spaced apart from each other in the first direction DR1 such that a part of the via layer 19 is exposed in the area between the first sub-bank IBK1 and the second sub-bank IBK2.

The first and second electrodes 21 and 22 may be electrically connected to the light-emitting element ED, and a voltage (e.g., a predetermined or selectable voltage) may be applied to the first and second electrodes 21 and 22 so that the light-emitting element ED emits light. For example, the first and second electrodes 21 and 22 may be electrically connected to the light-emitting element ED disposed between the first electrode 21 and the second electrode 22 through the first and second contact electrodes 41 and 42 to be described below, and the electrical signals applied to the first and second electrodes 21 and 22 may be transmitted to the light-emitting element ED through the first and second contact electrodes 41 and 42.

The first and second electrodes 21 and 22 may be used to form an electric field in the sub-pixel SPX to align the light-emitting elements ED. The light-emitting elements ED may be disposed between the first electrode 21 and the second electrode 22 by an electric field formed on the first electrode 21 and the second electrode 22. In an embodiment, the light-emitting elements ED of the display device 10 may be injected onto the electrodes 21 and 22 through an inkjet printing process. In case that inks including the light-emitting elements ED are injected onto the electrodes 21 and 22, an alignment signal may be applied to the electrodes 21 and 22 to generate an electric field. The light-emitting elements ED dispersed in the inks may be aligned on the electrodes 21 and 22 by receiving the dielectrophoretic force by the electric field generated on the electrodes 21 and 22.

The first and second electrodes 21 and 22 may contain a transparent conductive material. For example, each of the first and second electrodes 21 and 22 may include a material such as indium tin oxide (ITO), indium zinc oxide (IZO), and indium tin zinc oxide (ITZO), but is not limited thereto. In some other embodiments, the first and second electrodes 21 and 22 may include a conductive material having high reflectivity. For example, the first and second electrodes 21 and 22 may include, as a material having high reflectivity, metal such as silver (Ag), copper (Cu), or aluminum (Al). The first and second electrodes 21 and 22 may reflect light, which may be emitted from the light-emitting element ED and proceeds toward the side surface of the first bank IBK (first sub-bank IBK1 and second sub-bank IBK2), to proceed in the display direction in each sub-pixel SPX. However, the disclosure is not limited thereto. The first and second electrodes 21 and 22 may have a structure in which at least one transparent conductive material and at least one metal layer having high reflectivity may be stacked each other, or may be formed as a layer including them. In an embodiment, the first and second electrodes 21 and 22 may have a stacked structure such as ITO/Ag/ITO, ITO/Ag/IZO, or ITO/Ag/ITZO/IZO, or may be an alloy including aluminum (Al), nickel (Ni), lanthanum (La), and the like.

A first insulating layer 51 may be disposed on the first and second electrodes 21 and 22. The first insulating layer 51 may be disposed on the first electrode 21 and the second electrode 22 so as to expose at least a part of the first electrode 21 and the second electrode 22. The first insulating layer 51 may be formed entirely on a surface of the first substrate 11 including the area between the first electrode 21 and the second electrode 22 to expose a part of the first electrode 21 and the second electrode 22.

The first insulating layer 51 may be formed to have a step (or height difference) such that a part of the top surface thereof is recessed between the first electrode 21 and the second electrode 22. The first insulating layer 51 may be formed such that a part of its top surface is recessed due to a step formed by a member (for example, the first electrode 21 and/or the second electrode 22) disposed thereunder. In some embodiments, an empty space may be formed between the light-emitting element 30 and the top surface of the first insulating layer 51, a part of which may be recessed due to the step formed between the first electrode 21 and the second electrode 22. A material forming a second insulating layer 52 which will be described below may fill the empty space between the first insulating layer 51 and the light-emitting element ED. However, the disclosure is not limited thereto, and the first insulating layer 51 may not have a step between the first electrode 21 and the second electrode 22. For example, the first insulating layer 51 may include a flat top surface to dispose the light-emitting element ED between the first electrode 21 and the second electrode 22.

The first insulating layer 51 may protect the first electrode 21 and the second electrode 22 while insulating them from each other. Further, it is possible to prevent the light-emitting element 30 disposed on the first insulating layer 51 from being damaged by direct contact with other members.

The second bank OBK may be disposed on the first insulating layer 51. Parts of the second bank OBK, which extend in the first direction DR1 and the second direction DR2 in plan view, may be arranged in a grid pattern. The second bank OBK may be disposed across the boundary of each sub-pixel SPX to delimit neighboring sub-pixels SPX.

The second bank OBK may be formed to have a height greater than that of the first bank IBK. The second bank OBK may serve to prevent an ink from overflowing to adjacent sub-pixels SPX during an inkjet printing process for aligning the light-emitting elements ED in the manufacturing process of the display device 10. In an embodiment, the second bank OBK may include an organic insulating material such as polyimide (PI), but is not limited thereto.

The light-emitting element ED may be disposed on the first insulating layer 51 between the first electrode 21 and the second electrode 22 such that an end thereof is located on the first electrode 21 and another end thereof is located on the second electrode 22.

The light-emitting element ED may have a shape extending in a direction. The extension direction of the light-emitting element ED disposed on the first and second electrodes 21 and 22 may be substantially perpendicular to the extension direction of the first and second electrodes 21 and 22. However, the disclosure is not limited thereto. Some of the light-emitting elements ED may be arranged such that the extension direction thereof is substantially perpendicular to the extension direction of the first and second electrodes 21 and 22, and some others of the light-emitting elements ED may be arranged such that the extension direction thereof is oblique to the extension direction of the first and second electrodes 21 and 22.

A second insulating layer 52 may be partially disposed on the light-emitting element ED. The second insulating layer 52 may be disposed on the light-emitting element ED disposed between the first electrode 21 and the second electrode 22 to expose both ends (or two ends) of the light-emitting element ED. The second insulating layer 52 may be disposed to partially surround the outer surface of the light-emitting element ED. The second insulating layer 52 may function to protect the light-emitting element ED and also fix the light-emitting element ED in a manufacturing process of the display device 10.

A part of the second insulating layer 52 disposed on the light-emitting element ED may have a shape extending in the second direction DR2 between the first electrode 21 and the second electrode 22 in plan view. For example, the second insulating layer 52 may form a linear or island-shaped pattern in each sub-pixel SPX.

Although not shown in the drawings, the material forming (or constituting) the second insulating layer 52 may be disposed between the first electrode 21 and the second electrode 22, and fill the empty space between the light-emitting element ED and the first insulating layer 51 formed by depression as described above.

The first and second contact electrodes 41 and 42 may be disposed on the second insulating layer 52. The first and second contact electrodes 41 and 42 may have a shape extending in a direction in plan view. Each of the first contact electrode 41 and the second contact electrode 42 may have a shape extending in the second direction DR2. The first contact electrode 41 and the second contact electrode 42 may be spaced apart from each other and disposed to face each other in the first direction DR1.

The first contact electrode 41 may be disposed on the first electrode 21. The first contact electrode 41 may contact the first electrode 21 exposed by the first insulating layer 51, and may contact an end of the light-emitting element ED exposed by the second insulating layer 52. Since the first contact electrode 41 may contact the first electrode 21 and an end of the light-emitting element ED, it may serve to electrically connect the light-emitting element ED to the first electrode 21.

A third insulating layer 53 may be disposed on the first contact electrode 41. The third insulating layer 53 may serve to electrically insulate the first contact electrode 41 and the second contact electrode 42 from each other. The third insulating layer 53 may be disposed to cover the first contact electrode 41, but may not be disposed on another end of the light-emitting element ED such that the light-emitting element ED can contact the second contact electrode 42.

The second contact electrode 42 may be disposed on the second electrode 22. The second contact electrode 42 may contact the second electrode 22 exposed by the first insulating layer 51, and may contact another end of the light-emitting element ED exposed by the second insulating layer 52 and the third insulating layer 53. The second contact electrode 42 may contact the another end of the light-emitting element ED and the second electrode 22 to electrically connect the light-emitting element ED to the second electrode 22.

In other words, an end of the light-emitting element ED exposed by the second insulating layer 52 may be electrically connected to the first electrode 21 through the first contact electrode 41, and another end of the light-emitting element ED may be electrically connected to the second electrode 22 through the second contact electrode 42.

The first and second contact electrodes 41 and 42 may include a conductive material. For example, they may include ITO, IZO, ITZO, aluminum (Al), or the like. As an example, the first and second contact electrodes 41 and 42 may each include a transparent conductive material, but are not limited thereto.

The fourth insulating layer 54 may be disposed entirely on the first substrate 11. The fourth insulating layer 54 may function to protect the members disposed on the first substrate 11 from the external environment.

Each of the first insulating layer 51, the second insulating layer 52, the third insulating layer 53, and the fourth insulating layer 54 described above may include an inorganic insulating material or an organic insulating material. In an embodiment, the first insulating layer 51, the second insulating layer 52, the third insulating layer 53, and the fourth insulating layer 54 may include an inorganic insulating material such as silicon oxide (SiOₓ), silicon nitride (SiNₓ), silicon oxynitride (SiOₓN_{y}), aluminum oxide (AlₓO_{y}), aluminum nitride (AlN), and the like. As another example, they may include an organic insulating material such as acrylic resin, epoxy resin, phenolic resin, polyamide resin, polyimide resin, unsaturated polyester resin, polyphenylene resin, polyphenylenesulfide resin, benzocyclobutene, cardo resin, siloxane resin, silsesquioxane resin, polymethylmethacrylate, polycarbonate, polymethylmethacrylate-polycarbonate synthetic resin, and the like. However, the disclosure is not limited thereto.

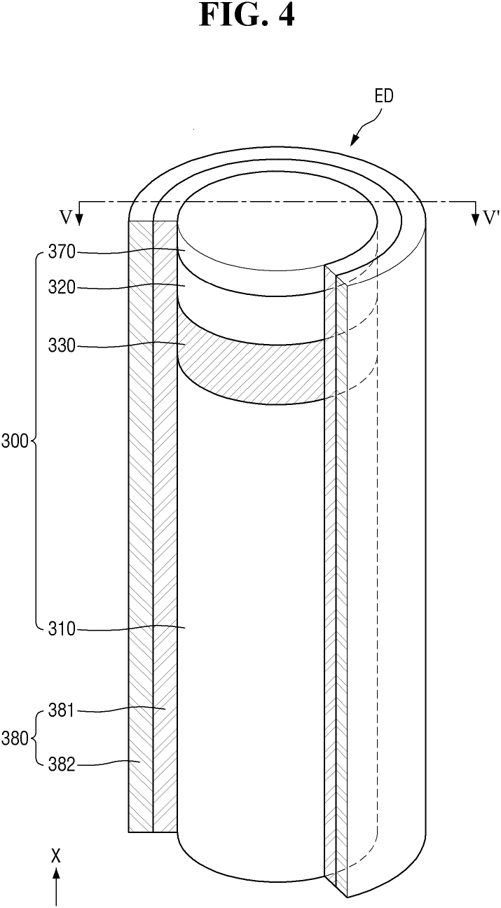

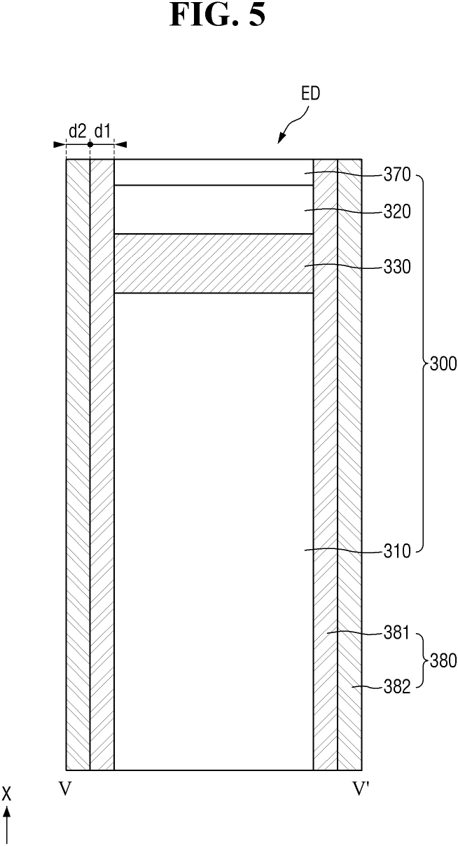

FIG. 4 is a schematic perspective view of a light-emitting element according to an embodiment. FIG. 5 is a schematic cross-sectional view taken along line V-V′ of FIG. 4.

The light-emitting element ED which is a particulate element may have a shape extending in a direction. The light-emitting element ED may have a rod, tube or cylindrical shape having an aspect ratio (e.g., a predetermined or selectable aspect ratio). The length of the light-emitting element ED may be larger than the diameter of the light-emitting element ED, and the aspect ratio may be about 1.2:1 to about 100:1, but the disclosure is not limited thereto.

The light-emitting element ED may have a size of a nanometer scale (equal to or greater than about 1 nm and less than about 1 µm) to a micrometer scale (equal to or greater than about 1 µm and less than about 1 mm). In an embodiment, both the diameter and the length of the light-emitting element ED may be on a nanometer scale, or on a micrometer scale. In some other embodiments, the diameter of the light-emitting element ED may be on a nanometer scale, while the length of the light-emitting element ED may be on a micrometer scale. In some embodiments, some of the light-emitting elements ED may have a diameter and/or length on a nanometer scale, while some others of the light-emitting elements ED may have a diameter and/or length on a micrometer scale.

The light-emitting element ED may include an inorganic light-emitting diode. The inorganic light-emitting diode may include semiconductor layers. For example, the inorganic light-emitting diode may include a first conductivity type (e.g., n-type) semiconductor layer, a second conductivity type (e.g., p-type) semiconductor layer, and an active semiconductor layer interposed therebetween. The active semiconductor layer may receive holes and electrons from the first conductivity type semiconductor layer and the second conductivity type semiconductor layer, respectively, and the holes and electrons that have reached the active semiconductor layer may be coupled to each other to emit light.

Referring to FIGS. 4 and 5, the light-emitting element (or light-emitting device) ED according to an embodiment includes a light-emitting element core (or light-emitting device core) 300, which have the semiconductor layers described above, and insulating layers 380 (381 and 382) which surround the outer circumferential surface of the light-emitting element core 300.

The light-emitting element core 300 may have a shape extending in a direction X. The shape of the light-emitting element core 300 may follow the shape of the light-emitting element ED. The shape of the light-emitting element core 300 may be a rod or cylindrical shape, similarly to the shape of the light-emitting element ED.

The light-emitting element core 300 may include a first semiconductor layer 310, an element active layer 330, and a second semiconductor layer 320 that may be sequentially stacked each other in the direction X that is a longitudinal direction of the light-emitting element ED. The first semiconductor layer 310, the element active layer 330, and the second semiconductor layer 320 may be the first conductivity type semiconductor layer, the active semiconductor layer, and the second conductivity type semiconductor layer described above, respectively.

Hereinafter, in the structural description of the light-emitting element ED, for simplicity of description, the term “upward” or “upper side” refers to a side of the direction X, which is the extension direction of the light-emitting element ED or the light-emitting element core 300, and the term “top surface” refers to a surface toward the side of the direction X. Further, the term “downward” or “lower side” refers to the other side of the direction X, which is the extension direction of the light-emitting element ED, and the term “bottom surface” refers to a surface toward the other side of the direction X.

The first semiconductor layer 310 may be a semiconductor layer doped with a first conductivity type dopant. The first conductivity type dopant may be Si, Ge, Sn, or the like. In an embodiment, the first semiconductor layer 310 may be n-GaN doped with n-type Si.

The second semiconductor layer 320 may be disposed on the first semiconductor layer 310 with the element active layer 330 interposed therebetween. The second semiconductor layer 320 may be spaced apart from the first semiconductor layer 310 in the direction X.

The second semiconductor layer 320 may be a semiconductor layer doped with a second conductivity type dopant. The second conductivity type dopant may be Mg, Zn, Ca, Se, Ba, or the like. In an embodiment, the second semiconductor layer 320 may be p-GaN doped with p-type Mg.

FIG. 4 illustrates that the first semiconductor layer 310 and the second semiconductor layer 320 may be configured as a single layer, the disclosure is not limited thereto. According to some embodiments, depending on the material of the element active layer 330, the first semiconductor layer 310 and the second semiconductor layer 320 may further include a larger number of layers, such as a cladding layer or a tensile strain barrier reducing (TSBR) layer.

The element active layer 330 may be disposed between the first semiconductor layer 310 and the second semiconductor layer 320. The element active layer 330 may include a material having a single or multiple quantum well structure. As described above, the element active layer 330 may emit light by coupling of electron-hole pairs according to an electrical signal applied through the first semiconductor layer 310 and the second semiconductor layer 320.

In some embodiments, the element active layer 330 may have a structure in which semiconductor materials having a large band gap energy and semiconductor materials having a small band gap energy are alternately stacked each other, and may include other group III to V semiconductor materials according to the wavelength band of the emitted light.

The light emitted from the element active layer 330 may be projected through both side surfaces as well as the outer surface of the light-emitting element ED in a longitudinal direction. For example, the directionality of light emitted from the element active layer 330 is not limited to a direction.

The light-emitting element core 300 may further include an electrode layer 370 disposed on the second semiconductor layer 320. The electrode layer 370 may contact the second semiconductor layer 320. The electrode layer 370 may be an ohmic contact electrode. However, the electrode layer 370 is not limited thereto, and may be a Schottky contact electrode. Although FIG. 4 illustrates that the top surface of the electrode layer 370 has a flat surface, the disclosure is not limited thereto. For example, the top surface of the electrode layer 370 may include surface roughness. A description of an embodiment in which the top surface of the electrode layer 370 includes surface roughness (e.g., a predetermined or selectable surface roughness) will be described below with reference to another drawing.

In case that both ends of the light-emitting element ED are electrically connected to the first and second electrodes 21 and 22 or the second contact electrodes 41 and 42 to apply an electrical signal to the first semiconductor layer 310 and the second semiconductor layer 320, the electrode layer 370 may serve to reduce resistance because it is disposed between the second semiconductor layer 320 and the first and second electrodes 21 and 22 or the second contact electrodes 41 and 42.

The electrode layer 370 may include a conductive metal. For example, the electrode layer 370 may include at least one of aluminum (Al), titanium (Ti), indium (In), gold (Au), silver (Ag), indium tin oxide (ITO), indium zinc oxide (IZO), or indium tin zinc oxide (ITZO). Further, the electrode layer 370 may include an n-type or p-type doped semiconductor material.

The insulating layer 380 may be disposed to surround the outer circumferential surface of the light-emitting element core 300. The insulating layer 380 may include a first insulating layer 381 and a second insulating layer 382.

The first insulating layer 381 may be disposed to surround the outer circumferential surface (or side surface) of the light-emitting element core 300. Specifically, the first insulating layer 381 may be disposed to surround the outer circumferential surfaces (or side surfaces) of the first semiconductor layer 310, the element active layer 330, and the second semiconductor layer 320 of the light-emitting element core 300. The first insulating layer 381 may be disposed to directly contact the side surfaces of the first semiconductor layer 310, the element active layer 330, and the second semiconductor layer 320. A part of the first insulating layer 381 may also be disposed on the side surface of the electrode layer 370 of the light-emitting element core 300. The first insulating layer 381 may be formed to surround the side surfaces of the members and extend in the direction X in which the light-emitting element ED extends.

The first insulating layer 381 may function to protect the members, for example, the first semiconductor layer 310, the element active layer 330, the second semiconductor layer 320, and the electrode layer 370. Since the first insulating layer 381 is disposed to surround the side surface of the element active layer 330, and includes a material capable of minimizing carrier loss that may occur at the interface between the element active layer 330 and the first insulating layer 381, it may serve to prevent a decrease in light efficiency of the light-emitting element ED.

The first insulating layer 381 may include at least one of materials having first fixed charges and an insulating property, for example, SiOₓ, SiNₓ, SiON, SiOₓN_{y}, AlₓO_{y}, HfO₂, SiO₂, TiO₂, SrTiO₃, Ta₂O₅, Gd₂O₃, ZrO₂, Ga₂O₃, V₂O₅, Co₃O₄, ZnO, ZnO:Al, ZnO:B, In₂O₃:H, WO₃, MoO₃, Nb₂O₅, NiO, MgO, RuO₂, MgF₂, AlF₃, Alucone, TiN, TaN, Si₃N₄, AlN, GaN, WN, HfN, NbN, GdN, VN, and ZrN. Since the first insulating layer 381 surrounding the members includes an insulating material, it is possible to prevent an electrical short circuit that may occur in case that the element active layer 330 directly contacts the first electrode 21 or the second electrode 22. Since the first insulating layer 381 protects the outer circumferential surface of the light-emitting element ED as well as the element active layer 330, it is possible to prevent a decrease in luminous efficiency by damage to the light-emitting element ED that may occur in a manufacturing process of the display device 10, which will be described below.

A thickness d1 of the first insulating layer 381 may be in a range of about 5 nm to about 100 nm, but is not limited thereto.

The second insulating layer 382 may be disposed to surround the outer circumferential surface of the first insulating layer 381. The second insulating layer 382 may be disposed to surround the outer circumferential surface of the first insulating layer 381 to perform the function of protecting the first insulating layer 381. For example, the second insulating layer 382 may be disposed to surround the first insulating layer 381, and thus it may serve to prevent the first insulating layer 381 of the light-emitting element ED from being damaged in a process of forming the second insulating layer 52 and/or the third insulating layer 53 during the manufacturing process of the display device 10, which will be described below. FIGS. 4 and 5 illustrate that the second insulating layer 382 is disposed to completely cover the outer circumferential surface of the first insulating layer 381, but the disclosure is not limited thereto. For example, the second insulating layer 382 may expose a part of the outer circumferential surface of the first insulating layer 381 at an end of the light-emitting element ED where the electrode layer 370 is disposed. A description thereof will be given below with reference to other drawings.

According to an embodiment, the second insulating layer 382 may have an insulating property and also include a material having second fixed charges that are different from the first fixed charges of the material included in the first insulating layer 381. The relative relationship between the fixed charges of the first and second insulating layers 381 and 382 will be described below in detail. For example, the second insulating layer 382 may include at least one of the insulating materials listed as materials that the first insulating layer 381 may include.

In an embodiment, in case that the first insulating layer 381 includes silicon oxide (SiOx) having a first fixed charge, the second insulating layer 382 may include aluminum oxide (AlxOy) having a second fixed charge that may be different from the first fixed charge. However, the disclosure is not limited thereto, and the first insulating layer 381 and the second insulating layer 382 may include materials having different fixed charges from each other among the materials listed as materials having an insulating property.

A thickness d2 of the second insulating layer 382 may be in a range of about 5 nm to about 100 nm, but is not limited thereto.

Although FIG. 5 illustrates that the thickness d1 of the first insulating layer 381 and the thickness d2 of the second insulating layer 382 are the same or each to each other, the disclosure is not limited thereto. In some embodiments, the thickness d1 of the first insulating layer 381 may be different from the thickness d2 of the second insulating layer 382. For example, the thickness d1 of the first insulating layer 381 may be greater than the thickness d2 of the second insulating layer 382. As another example, the thickness d1 of the first insulating layer 381 may be smaller than the thickness d2 of the second insulating layer 382.

Hereinafter, the relative relationship between the fixed charges of the materials included in the first insulating layer 381 and the second insulating layer 382 and the relationship between the element active layer 330 and the first insulating layer 381 will be described. In the following description, the term “fixed charge” does not refer to the total amount of charges contained in each of the insulating layers 381 and 382, but refers to the density of the fixed charges in a region adjacent to the interface (surface) of each insulating layer 381 or 382. The unit of the fixed charge may be “cm⁻²”. In case that the fixed charge has a positive (+) value, it may have a positive fixed charge, and in case that it has a negative (-) value, it may have a negative fixed charge.

On the other hand, the efficiency of the light-emitting element ED may depend on characteristics of an interface (or surface) where the element active layer 330 emitting light and the first insulating layer 381 contact each other. For example, the efficiency of the light-emitting element ED may be affected by loss at the interface (or the surface), where the element active layer 330 emitting light and the first insulating layer 381 contact each other, due to carrier movement from the element active layer 330 to the first insulating layer 381. Accordingly, in order to prevent the loss due to the carrier movement or electron-hole recombination at the interface where the element active layer 330 and the first insulating layer 381 contact each other, the material included in the first insulating layer 381, which is disposed to surround the side surface of the element active layer 330, may be a material that has a first fixed charge and has a property in which carriers hardly move from the element active layer 330 to the first insulating layer 381.

The first fixed charge of the first insulating layer 381 may be a negative fixed charge or a positive fixed charge. In an embodiment, in case that the first fixed charge is a negative fixed charge, a negative fixed charge layer may be formed at the interface between the first insulating layer 381 and the element active layer 330. Accordingly, since the interface of the first insulating layer 381 has a negative charge property, the movement of carriers, for example, electrons, from the element active layer 330 to the first insulating layer 381 may be prevented. Accordingly, carrier loss, which is caused by the movement of carriers from the element active layer 330 to the first insulating layer 381 at the interface between the element active layer 330 and the first insulating layer 381,,may be decreased, so that the luminous efficiency of the light-emitting element ED may be improved. However, the disclosure is not limited thereto, and the first fixed charge may have a positive fixed charge.

As described above, the second insulating layer 382 may include a material that has the second fixed charge different from the first fixed charge. For example, the fixed charge of the material included in the first insulating layer 381 may be different from the fixed charge of the material included in the second insulating layer 382.

In an embodiment, the polarity of the first fixed charge and the polarity of the second fixed charge may be the same as each other or identical to each other. For example, in case that the first and second fixed charges have positive (+) fixed charges, the absolute value of the first fixed charge may be smaller than the absolute value of the second fixed charge. In some other embodiments, in case that the first and second fixed charges have negative (-) fixed charges, the absolute value of the first fixed charge may be greater than the absolute value of the second fixed charge. However, the disclosure is not limited thereto. In the following description, the fact that “the magnitude of the fixed charge is large” may mean that the absolute value of the fixed charge is large.

In some embodiments, the polarity of the first fixed charge and the polarity of the second fixed charge may be different from each other. For example, the polarity of the first fixed charge may be negative (-), and the polarity of the second fixed charge may be positive (+). For example, the first fixed charge may have a negative fixed charge, and the second fixed charge may have a positive fixed charge. The first insulating layer 381, which surrounds the element active layer 330 while contacting the side surface thereof, includes a material having a negative fixed charge or a material having a positive fixed charge with a small absolute value, so that the carrier movement from the element active layer 330 to the first insulating layer 381 may be prevented. Accordingly, it is possible to prevent a decrease in efficiency of the light-emitting element ED due to carrier loss which may occur at the interface between the first insulating layer 381 and the element active layer 330.

As described above, in case that the first insulating layer 381 includes silicon oxide (SiOx) having the first fixed charge and the second insulating layer 382 includes aluminum oxide (AlxOy) having the second fixed charge, the first fixed charge and the second fixed charge may have positive fixed charges, and the magnitude of the first fixed charge may be smaller than the magnitude of the second fixed charge. As another example, the first fixed charge may have a negative fixed charge, and the second fixed charge may have a positive fixed charge. Similarly, the first fixed charge and the second fixed charge may have negative fixed charges, and the magnitude of the first fixed charge may be greater than the magnitude of the second fixed charge.

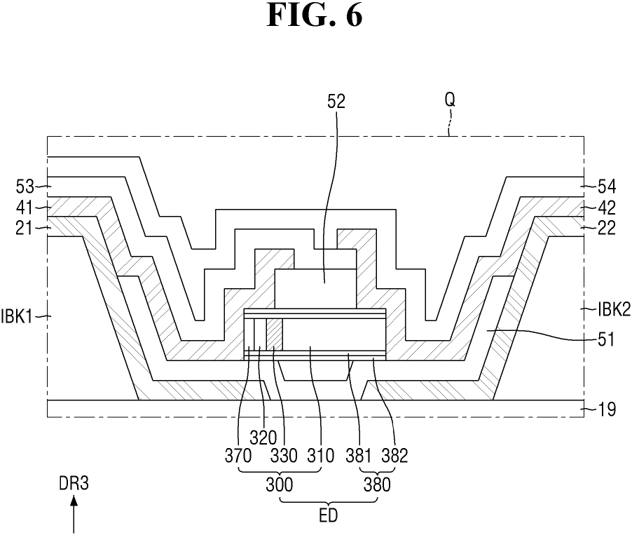

The second insulating layer 382 may include a material that has a fixed charge different from that of the material of the first insulating layer 381, thereby improving light emission characteristics of the light-emitting element ED included in the display device 10. Also, the second insulating layer 382 may include a material that has a different etch selectivity from that of the first insulating layer 381 with respect to a same etchant. Since the second insulating layer 382 includes a material that has a different etch selectivity from that of the first insulating layer 381 with respect to a same etchant, the second insulating layer 382 may prevent the first insulating layer 381 from being damaged by an etchant used in the process for forming the insulating layers disposed on the light-emitting element ED, for example, the second to fourth insulating layers 52, 53, and 54 (see FIG. 3) during the manufacturing process of the display device 10. A detailed description thereof will be given below with reference to FIG. 6.

FIGS. 4 and 5 illustrate that the first insulating layer 381 and the second insulating layer 382 are formed to cover a region from the side surface of the first semiconductor layer 310 to the side surface of the electrode layer 370, but the disclosure is not limited thereto. The first insulating layer 381 and/or the second insulating layer 382 may be disposed to cover the side surfaces of the first semiconductor layer 310, the second semiconductor layer 320, and the element active layer 330 while exposing at least a part of the side surface of the electrode layer 370. Also, the first insulating layer 381 and/or the second insulating layer 382 may be formed to have a rounded top surface in a region adjacent to at least one end of the light-emitting element ED in a cross-sectional view.

Also, in some embodiments, the outer circumferential surface of the second insulating layer 382 may be surface-treated. As described above, the light-emitting element ED may be applied in a dispersed state in a solution to be aligned between the first electrode 21 and the second electrode 22. In order to keep the light-emitting elements ED in the dispersed state without being aggregated with adjacent other light-emitting elements ED in the solution, the surface of the second insulating layer 382 may be treated to have a hydrophobic or hydrophilic property so that they may remain dispersed from each other in the solution. Accordingly, in case that the light-emitting elements ED are aligned, the light-emitting elements ED may be aligned without being aggregated with each other between the first electrode 21 and the second electrode 22.

FIG. 6 is a schematic enlarged view illustrating an example of part Q of FIG. 3.

Referring to FIGS. 3 and 6, the light-emitting element ED may be disposed on the first substrate 11. The light-emitting element ED may be disposed on the first insulating layer 51 between the first electrode 21 and the second electrode 22. In a cross-sectional view traversing the both ends of the light-emitting element ED, the first semiconductor layer 310, the element active layer 330, the second semiconductor layer 320, and the electrode layer 370 may be sequentially formed in a direction parallel with a surface of the first substrate 11, and the first insulating layer 381 and the second insulating layer 382 may be formed in a direction perpendicular to the surface of the first substrate 11.

The first insulating layer 381 of the light-emitting element ED may be disposed to surround the side surfaces of the first semiconductor layer 310, the element active layer 330, the second semiconductor layer 320, and the electrode layer 370, and the second insulating layer 382 may be disposed to surround the first insulating layer 381. Accordingly, the outer surface of the light-emitting element ED, which is disposed between the first electrode 21 and the second electrode 22 while both ends thereof are respectively located above the first electrode 21 and the second electrode 22, may be the second insulating layer 382. Parts of the second insulating layer 382 may contact the first insulating layer 51 disposed thereunder and the second insulating layer 52 disposed thereabove, respectively.

The both ends of the light-emitting element ED exposed by the second insulating layer 52 may contact the first contact electrode 41 and the second contact electrode 42. Specifically, the second insulating layer 382 and the electrode layer 370 of the light-emitting element ED exposed by the second insulating layer 52 may contact the first contact electrode 41, and the second insulating layer 382 and the first semiconductor layer 310 of the light-emitting element ED exposed by the second insulating layer 52 may contact the second contact electrode 42. Accordingly, in the region where the first and second contact electrodes 41 and 42 and the second insulating layer 382 contact each other, the second insulating layer 382 may be interposed between the first and second contact electrodes 41 and 42 and the first insulating layer 381.

The first insulating layer 381 of the light-emitting element ED may be disposed to surround the side surfaces of the first semiconductor layer 310, the element active layer 330, the second semiconductor layer 320, and the electrode layer 370 to protect the members. Since the first insulating layer 381 of the light-emitting element ED includes a material having the first fixed charge, it is possible to prevent leakage of electron-hole coupling due to carriers moving from the element active layer 330 to the first insulating layer 381. Accordingly, the first insulating layer 381 including a material having the first fixed charge may be formed to surround the side surfaces of the first semiconductor layer 310, the element active layer 330, the second semiconductor layer 320, and the electrode layer 370, thereby insulating and protecting the members from external members, and preventing a decrease in the luminous efficiency of the light-emitting element ED.

The second insulating layer 382 of the light-emitting element ED may be disposed to surround the first insulating layer 381, and thus it may serve to protect the first insulating layer 381. For example, during the manufacturing process of the display device 10, the outer surface of the light-emitting element ED may be exposed to an etchant used in the process of forming the second insulating layer 52 and/or the third insulating layer 53. Specifically, the second insulating layer 382 of the light-emitting element ED may be exposed to an etchant used in the process of forming the second insulating layer 52 and/or the third insulating layer 53. The second insulating layer 382 may include a material that has the second fixed charge different from the first fixed charge of the material included in the first insulating layer 381. Accordingly, since the second insulating layer 382 includes a material different from that of the first insulating layer 381, for example, the material having the second fixed charge that is different from the first fixed charge, it may protect the first insulating layer 381 from the etchant.

In this embodiment, since the display device 10 includes the light-emitting element ED that has the first insulating layer 381 having the first fixed charge described above, luminance deterioration of the light-emitting element ED may be improved. Since the light-emitting element ED includes the second insulating layer 382 that has the second fixed charge different from the first fixed charge while surrounding the first insulating layer 381, the second insulating layer 382 may protect the first insulating layer 381 in the process of forming or patterning the insulating layers of the display device 10. Therefore, in this case, even in case that an etch selectivity of an etchant, which is used in the process of forming or patterning the second insulating layer 52 (or the third insulating layer 53), with respect to the second insulating layer 52 (or the third insulating layer 53) is similar to an etch selectivity thereof with respect to the first insulating layer 381, the second insulating layer 382 including the material different from that of the first insulating layer 381 may protect the first insulating layer 381 in the manufacturing process of the display device 10. Accordingly, since the display device 10 includes the light-emitting element ED having improved luminance efficiency, light output efficiency of the display device 10 may be improved.

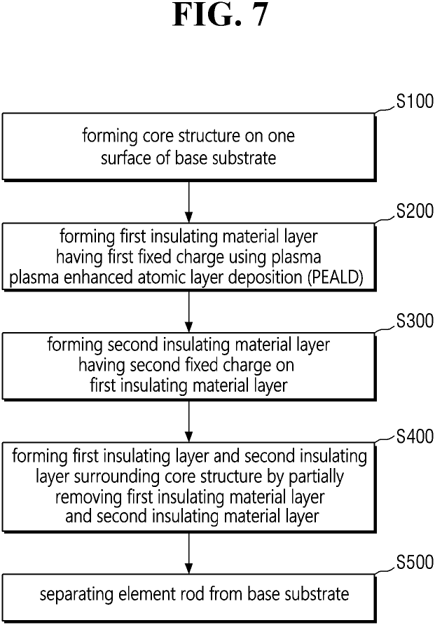

FIG. 7 is a schematic flowchart illustrating a method of manufacturing a light-emitting element according to an embodiment.

Referring to FIG. 7, the method of manufacturing the light-emitting element ED according to an embodiment may include forming a core structure on a surface of a base substrate (step S100), forming a first insulating material layer (or first insulating layer) that includes a material having a first fixed charge on the core structure using plasma enhanced atomic layer deposition (PEALD) (step S200), forming a second insulating material layer (or second insulating layer) that includes a material having a second fixed charge different from the first fixed charge on the first insulating material layer (step S300), forming an element rod by exposing the top surface of the core structure by partially removing the first insulating material layer and the second insulating material layer (step S400), and separating the element rod from the base substrate (step S500).

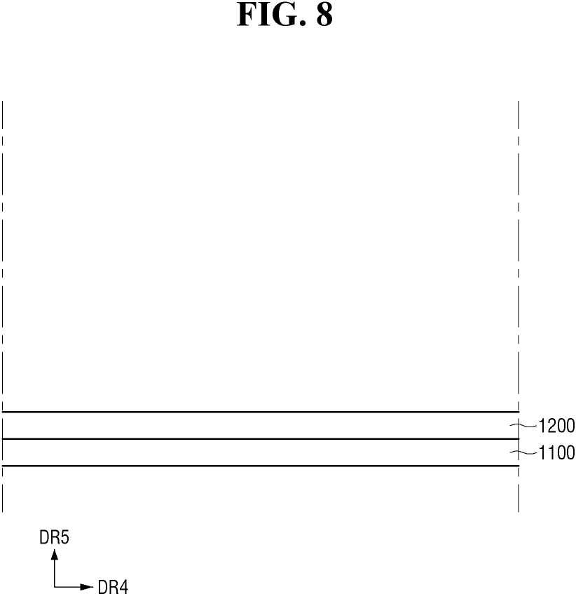

In this embodiment, the first insulating layer 381 surrounding the side surface of the light-emitting element core 300 may be formed by forming the first insulating material layer using plasma enhanced atomic layer deposition (PEALD), forming the second insulating material layer on the first insulating material layer, and vertically etching the first insulating material layer and the second insulating material layer to partially remove them and expose the top surface of the light-emitting element core 300 in the subsequent process. Hereinafter, a manufacturing process of the light-emitting element ED according to an embodiment will be described with reference to FIGS. 8 to 14.

FIGS. 8 to 14 are schematic cross-sectional views illustrating the manufacturing process of a light-emitting element according to an embodiment.

First, a core structure is formed on a surface of a base substrate (S100) (see FIG. 7).

The step S100 of forming a core structure 300′ on a surface of a base substrate 1100 may include preparing the base substrate 1100, forming a first stacked structure 3000 on the base substrate 1100, and forming the core structures 300′ by etching the first stacked structure 3000 in a direction perpendicular to the top surface of the base substrate 1100.

Specifically, referring to FIG. 8, the base substrate 1100 is prepared.

In the following, a fourth direction DR4 and a fifth direction DR5 may be defined in the drawings of the embodiment illustrating the manufacturing process of the light-emitting element ED. The fourth direction DR4 and the second direction DF5 may be perpendicular to each other. The fifth direction DR5 may be a direction parallel to the direction X, which is the extension direction of the light-emitting element ED formed on the base substrate 1100. In the embodiment describing the manufacturing process of the light-emitting element ED, unless otherwise stated, “upward” may indicate a side of the fifth direction DR5, e.g., a direction in which the semiconductor layers of the light-emitting element ED are stacked each other from a surface (or top surface) of the base substrate 1100, and “top surface” may indicate a surface toward the side of the fifth direction DR5. Further, the term “downward” may refer to the other side of the fifth direction DR5, and the term “bottom surface” may refer to a surface toward the other side of the fifth direction DR5.

The base substrate 1100 may include a sapphire substrate (AlₓO_{y}) or a transparent substrate such as glass. In an embodiment, the base substrate 1100 may be a sapphire substrate (AlₓO_{y}).

Semiconductor layers included in the light-emitting element ED may be formed on a surface of the base substrate 1100. The semiconductor layers included in the light-emitting element ED may be formed by forming a seed crystal on the base substrate 1100 and growing it by an epitaxial method. The semiconductor layer may be formed by electron beam deposition, physical vapor deposition (PVD), chemical vapor deposition (CVD), plasma laser deposition (PLD), dual-type thermal evaporation, sputtering, or metal organic chemical vapor deposition (MOCVD).

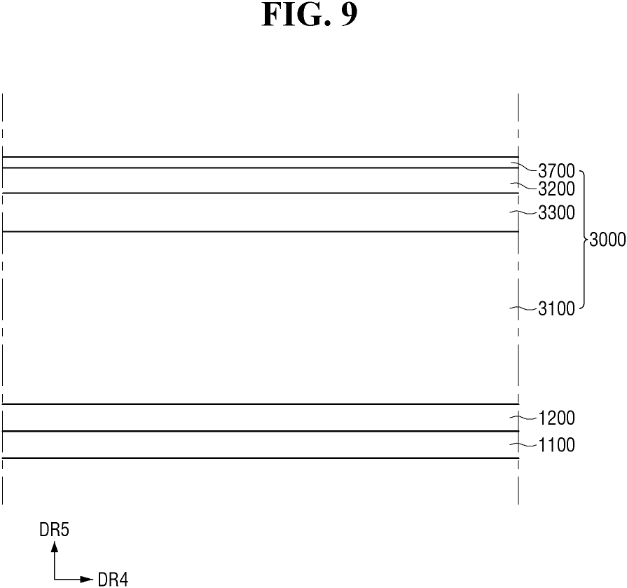

A buffer material layer (or buffer layer) 1200 may be formed on a surface (or a top surface) of the base substrate 1100. The buffer material layer 1200 may serve to reduce a lattice constant difference between the base substrate 1100 and a first semiconductor material layer (or first semiconductor layer) 3100 (see FIG. 9) to be described below. The buffer material layer 1200 may include an undoped semiconductor. The buffer material layer 1200 and the first semiconductor layer 3100 to be described below may include a same material, but the buffer material layer 1200 may include a material not doped with the first conductivity type dopant or the second conductivity type dopant, e.g., an n-type or p-type dopant. Although FIG. 8 illustrates that the buffer material layer 1200 is stacked as a single layer, the buffer material layer 1200 may be formed as layers.

The buffer material layer 1200 may be omitted depending on the type of the base substrate 1100.

The first stacked structure 3000 is formed above the base substrate 1100.

Referring to FIG. 9, in an embodiment in which the buffer material layer 1200 is formed on the base substrate 1100, the first stacked structure 3000, which includes the first semiconductor material layer 3100, an element active material layer (or element active layer) 3300, a second semiconductor material layer (or second semiconductor layer) 3200, and an electrode material layer (or electrode layer) 3700 sequentially stacked therein, may be formed on the buffer material layer 1200. The material layers included in the first stacked structure 3000 may be formed by performing conventional processes.

The layers included in the first stacked structure 3000 may correspond to the respective layers included in the light-emitting element ED according to an embodiment. Specifically, the first semiconductor material layer 3100, the element active material layer 3300, the second semiconductor material layer 3200, and the electrode material layer 3700 of the first stacked structure 3000 may respectively correspond to the first semiconductor layer 310, the element active layer 330, the second semiconductor layer 320, and the electrode layer 370 of the light-emitting element ED, and may include the same materials as the materials included in the respective layers.

Subsequently, the first stacked structure 3000 may be etched to form the core structures 300′ that are spaced apart from each other above the base substrate 1100.

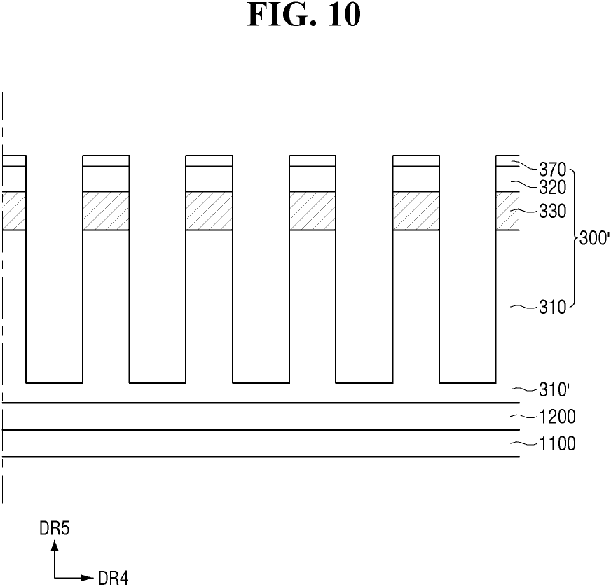

Referring to FIG. 10, the core structures 300′ spaced apart from each other may be formed by etching the first stacked structure 3000 in a direction perpendicular to a surface of the base substrate 1100 (e.g., a fifth direction DR5). In the etching process for forming the core structure 300′, the first semiconductor material layer 3100 of FIG. 9 may be etched to remain above the base substrate 1100 with a thickness (e.g., a predetermined or selectable thickness), so that parts of the first semiconductor material layer 3100 may be etched to become first semiconductor layers 310 patterned, and other parts thereof may remain unetched to become a first semiconductor connection layer 310′.

The etching process of the first stacked structure 3000 to form the core structure 300′ may be performed by a conventional method. In an embodiment, the core structure 300′ may be formed by forming an etch mask layer on the first stacked structure 3000, and etching the first stacked structure 3000 along the etch mask layer in a direction perpendicular to a surface of the base substrate 1100, for example, the fifth direction DR5.

For example, the etching process of etching the first stacked structure 3000 to form the core structure 300′ may be performed by dry etching, wet etching, reactive ion etching (RIE), inductively coupled plasma reactive ion etching (ICP-RIE), or the like. In an embodiment, the etching process of forming the core structure 300′ to allow the side surface of the core structure 300′ to be perpendicular to a surface of the base substrate 1100 may be performed by mixing the dry etching method and the wet etching method. Specifically, the first stacked structure 3000 may be etched in the fifth direction DR5 by the dry etching method which is anisotropic etching, and an etching process may be performed by the wet etching method which is isotropic etching so that a lateral side (or a side surface) of a structure resulting from etching of the first stacked structure 3000 is arranged on a plane perpendicular to the surface of the base substrate 1100, thereby forming the core structures 300′.

The core structures 300′ may be spaced apart from each other on the first semiconductor connection layer 310′. Each of the core structures 300′ may include the first semiconductor layer 310, the element active layer 330, the second semiconductor layer 320, and the electrode layer 370 that are sequentially stacked each other on the first semiconductor connection layer 310′ in an upward direction (the fifth direction DR5).

The first semiconductor layer 310 may be integral with the first semiconductor connection layer 310′. The first semiconductor layer 310 may have a structure protruding from the first semiconductor connection layer 310′, which is disposed entirely on the buffer material layer 1200, in the fifth direction DR5. For example, the first semiconductor layer 310 and the first semiconductor connection layer 310′ may include a same material, may be integral with each other, and may have a structure having different steps. Accordingly, the first semiconductor layers 310 of the core structures 300′ formed on the first semiconductor connection layer 310′ may be integrated by the first semiconductor connection layer 310′ to be physically and/or electrically connected to each other.

A first insulating material layer 3810 including a material having the first fixed charge may be formed on the core structures 300′ using plasma enhanced atomic layer deposition (PEALD) (step S200) (see FIG. 7).

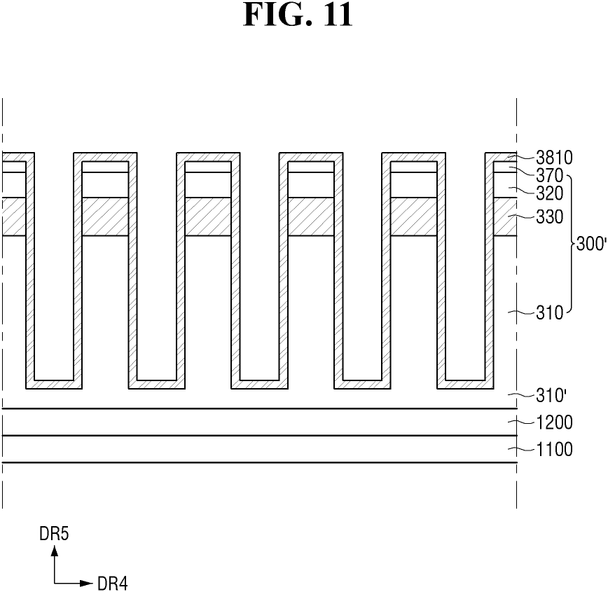

Referring to FIG. 11, the first insulating material layer 3810 may be formed on the outer surface of the core structure 300′. Since the first insulating material layer 3810 is formed above the entire surface of the base substrate 1100, it may be formed not only on the outer surface of the core structure 300′, but also on the top surface of the first semiconductor connection layer 310′ exposed by the core structure 300′. The outer surface of the core structure 300′ may include the side surface and the top surface of the core structure 300′.

The first insulating material layer 3810 may correspond to the first insulating layer 381 of the light-emitting element ED through a subsequent process. Accordingly, the first insulating material layer 3810 may include a material included in the first insulating layer 381, for example, an insulating material having the first fixed charge. For example, the first insulating material layer 3810 may include at least one of the insulating materials listed as materials that the first insulating layer 381 may include. In an embodiment, the first insulating material layer 3810 may include silicon oxide (SiOₓ) having the first fixed charge.

In an embodiment, the first insulating material layer 3810 may be formed using a method of coating or immersing an insulating material on the outer surface of the core structure 300′, and the like. In an embodiment, the first insulating material layer 3810 may be formed using plasma enhanced atomic layer deposition (PEALD).

In an embodiment in which the first insulating material layer 3810 includes silicon oxide (SiOₓ) having the first fixed charge, the step of forming the first insulating material layer 3810 by a plasma enhanced atomic layer deposition (PEALD) process may include providing a precursor on the core structure 300′, purging, providing a reactive gas on the core structure 300′, generating plasma of the reactive gas on the core structure, and purging.

A precursor may be provided on the core structure 300′. Specifically, in an embodiment in which the first insulating material layer 3810 includes silicon oxide (SiOₓ), the precursor may include a silicon-containing precursor. A purge gas may be provided to remove unreacted materials and by-products that may remain in a reactor. Subsequently, a reactive gas may be provided onto the core structure 300′. The reactive gas may include oxygen. Power may be supplied to the core structure 300′ to generate plasma. Power for generating the plasma may be about 200 W, and a process temperature may be in a range of about 150° C. to about 250° C., but the disclosure is not limited thereto. Thereafter, a purge gas may be provided to remove unreacted materials and by-products that may remain in the reactor.

A second insulating material layer 3820, which includes a material having the second fixed charge different from the first fixed charge, may be formed on the first insulating material layer 3810 (step S300) (see FIG. 7).

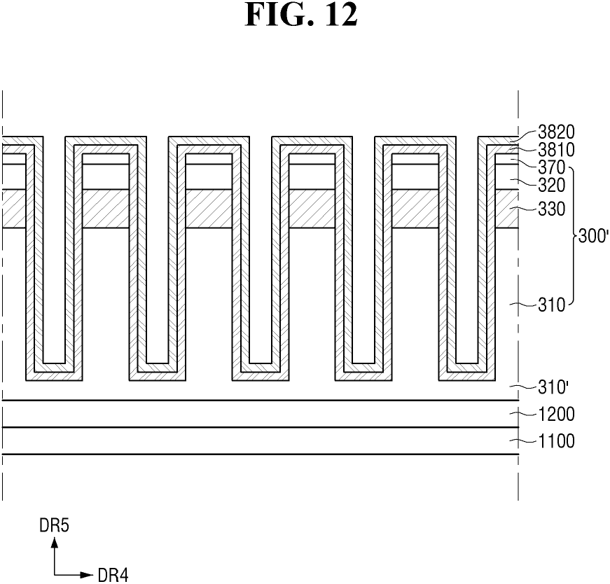

Referring to FIG. 12, the second insulating material layer 3820 may be formed on the outer surface of the first insulating material layer 3810. The second insulating material layer 3820 may be formed on the entire surface of the first insulating material layer 3810.

The second insulating material layer 3820 may include a material having the second fixed charge different from the first fixed charge of the first insulating material layer 3810. The second insulating material layer 3820 may be formed using a method of coating or immersing an insulating material on the outer surface of the first insulating material layer 3810, and the like. For example, the second insulating material layer 3820 may be formed by thermal atomic layer deposition (thermal ALD) or plasma enhanced atomic layer deposition (PEALD).

Although FIG. 12 illustrates that the first insulating material layer 3810 and the second insulating material layer 3820 are respectively formed through separate deposition processes, the disclosure is not limited thereto. The first insulating material layer 3810 and the second insulating material layer 3820 may be formed by simultaneous deposition in a process. Similar to the first insulating material layer 3810, the second insulating material layer 3820 may be formed using plasma enhanced atomic layer deposition (PEALD).

The second insulating material layer 3820 may correspond to the second insulating layer 382 of the light-emitting element ED. Accordingly, the second insulating material layer 3820 may include a material included in the second insulating layer 382, for example, an insulating material having the second fixed charge different from the first fixed charge. The second insulating material layer 3820 and the first material insulating layer 3810 may include different materials. For example, the second insulating material layer 3810 may include an insulating material having the second fixed charge different from the first fixed charge among the insulating materials listed as materials that the first insulating layer 381 may include. In an embodiment, the second insulating material layer 3820 may include aluminum oxide (AlₓO_{y}) having the second fixed charge.

The first insulating material layer 3810 and the second insulating material layer 3820 may be partially removed to expose the top surface of the core structure 300′, thereby forming an element rod ROD (step S400) (see FIG. 7).

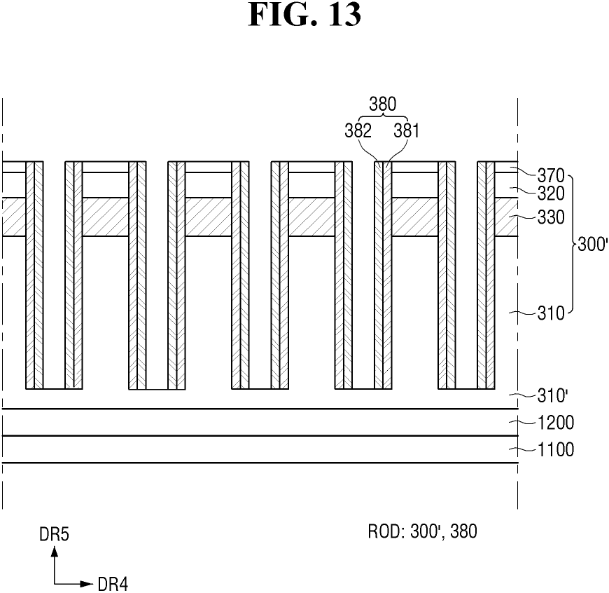

Referring to FIG. 13, the element rod ROD may include the core structure 300′, the first insulating layer 381 surrounding the side surface of the core structure 300′, and the second insulating layer 382 surrounding the outer circumferential surface of the first insulating layer 381.

In order to electrically connect the first semiconductor layer 310 and the second semiconductor layer 320 of the light-emitting element ED to the first and second contact electrodes 41 and 42 described above, the insulating layers disposed at both ends of the light-emitting element ED need to be removed to expose both end surfaces of the light-emitting element ED. Accordingly, the first insulating material layer 3810 and the second insulating material layer 3820 formed on the top surface of the core structure 300′, which are shown in FIG. 12, may be removed to expose the top surface of the core structure 300′, thereby forming the element rod ROD. A process such as etch back or dry etching that is anisotropic etching may be performed to remove parts of the first insulating material layer 3810 and the second insulating material layer 3820.

The element rod ROD may be separated from the base substrate 1100 (S500) (see FIG. 7).

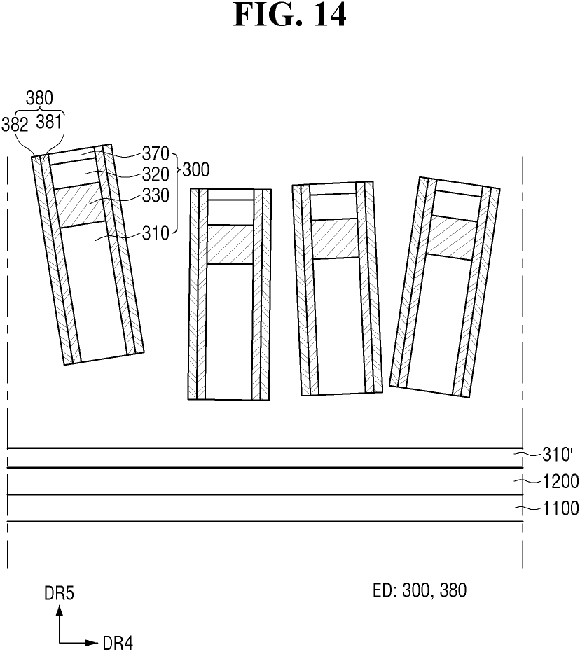

Referring to FIG. 14, the light-emitting element ED according to an embodiment may be manufactured by removing, from the base substrate 1100, the element rod ROD including the core structure 300′, the first insulating layer 381, and the second insulating layer 382 that correspond to the respective members of the light-emitting element ED including the first insulating layer 381, the second insulating layer 382, and the light-emitting element core 300 including the first semiconductor layer 310, the element active layer 330, the second semiconductor layer 320, and the electrode layer 370.

A method of separating the element rod ROD from the base substrate 1100 is not particularly limited. The process of separating the element rod ROD from the base substrate 1100 may be performed by a physical separation method or a chemical separation method.

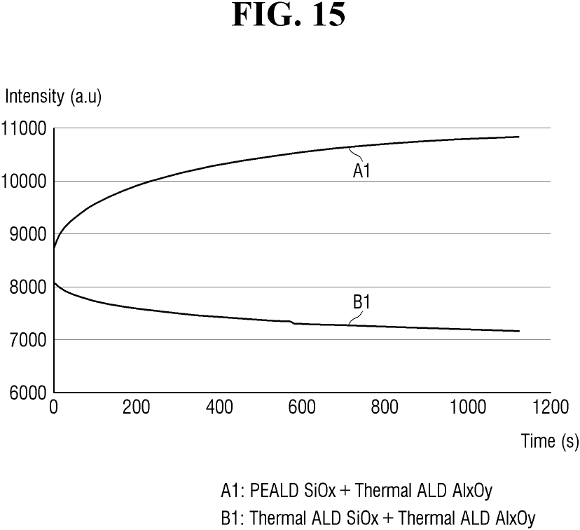

FIG. 15 is a schematic graph that compares light emission characteristics of light-emitting elements according to first insulating layers formed by plasma enhanced atomic layer deposition (PEALD) and thermal atomic layer deposition (thermal ALD), respectively, in case that the first insulating layers include silicon oxide (SiOₓ).

In the graph of FIG. 15, an X axis represents time in case that an electrical signal is applied to the light-emitting element ED, and a Y axis represents a luminance intensity of light emitted from the light-emitting element ED. In the following description of the graph illustrating the luminance intensity of light according to the time when an electrical signal is applied to the light-emitting element ED with reference to FIG. 15, “luminance intensity of light” will be referred to as “luminance of light” for simplicity of description. As shown in FIG. 15, in case that an electrical signal is applied to the light-emitting element ED, light emitted from the light-emitting element ED may have a different luminance distribution according to the time when the electrical signal is applied. Each of line A1 and line B1 illustrated in FIG. 15 illustrates the luminance distribution of light of the light-emitting element ED according to an embodiment in which the first insulating layer 381 includes silicon oxide (SiOₓ) and the second insulating layer 382 includes aluminum oxide (AlₓO_{y}).

Line A1 of FIG. 15 illustrates the luminance distribution of light according to the time when an electrical signal is applied, in the case of the light-emitting element ED in which the first insulating layer 381 including silicon oxide (SiOₓ) is formed using plasma enhanced atomic layer deposition (PEALD), and the second insulating layer 382 including aluminum oxide (AlₓO_{y}) is formed using thermal atomic layer deposition (ALD). Line B1 of FIG. 15 illustrates the luminance distribution of light according to the time when an electrical signal is applied, in the case of the light-emitting element ED in which the first insulating layer 381 including silicon oxide (SiOₓ) and the second insulating layer 382 including aluminum oxide (AlₓO_{y}) are formed using thermal atomic layer deposition (ALD).

Referring to line A1 of FIG. 15, in the case (line A1) of the light-emitting element ED in which the first insulating layer 381 is formed using plasma enhanced atomic layer deposition (PEALD), and the second insulating layer 382 is formed using thermal atomic layer deposition (thermal ALD), as time passes after the electrical signal is applied to the light-emitting element ED, the luminance of the light emitted from the light-emitting element ED may increase, and may have a stable distribution after a specific time.

Referring to line B1 of FIG. 15, in the case (line B1) of the light-emitting element ED in which the first insulating layer 381 and the second insulating layer 382 are formed using thermal atomic layer deposition (thermal ALD), as time passes after the electrical signal is applied to the light-emitting element ED, the luminance of the light emitted from the light-emitting element ED may decrease, and may have a stable distribution after a specific time.

Initial luminance values (e.g., luminance values in case that electrical signal application time is 0) of line A1 and line B1 may be different from each other. As shown in FIG. 15, the initial luminance value of line A1 may be greater than the initial luminance value of line B1. Accordingly, since the initial luminance value of rising line A1 is greater than that of falling line B1, the luminance value of line A1 that increases over time may be greater than the luminance value of line B1. For example, the light-emitting element ED of line A1 may have higher luminous efficiency and reliability than the light-emitting element ED of line B1.

As shown in FIG. 15, it is seen that the luminance distributions of rays of light of the light-emitting elements ED in which the second insulating layers 382 are formed in the same manner by using thermal atomic layer deposition (thermal ALD) may be different depending on whether the process of forming the first insulating layer 381 is plasma atomic layer deposition (PEALD) or thermal atomic layer deposition (thermal ALD). For example, the light-emitting performance of the light-emitting element ED may depend on the deposition method of the first insulating layer 381.

In case that the process of forming the first insulating layer 381 is performed by atomic layer deposition (ALD), the thin-film characteristics of the first insulating layer 381 may depend on whether the energy source is thermal energy or thermal energy and plasma. For example, the light emission characteristic of the light-emitting element ED may depend on whether the process of forming the first insulating layer 381 is plasma enhanced atomic layer deposition (PEALD) or thermal atomic layer deposition (thermal ALD). For example, in the process of depositing the first insulating material layer 3810 to form the first insulating layer 381 (see FIG. 11), since the reactivity is relatively high in the case of using plasma enhanced atomic layer deposition (PEALD) compared to the case of using thermal atomic layer deposition (thermal ALD), the first insulating layer 381 may have high film density and/or great surface roughness. Accordingly, the light-emitting element ED may be manufactured by forming the first insulating layer (or insulating film) 381 using plasma enhanced atomic layer deposition (PEALD), so that the thin-film characteristics such as film density and/or surface roughness of the first insulating layer 381 may be improved, and therefore the light emission characteristics of the light-emitting element ED may be improved.

In the method of manufacturing the light-emitting element ED according to an embodiment, since the first insulating layer 381 including silicon oxide (SiOₓ), which includes a material having the first fixed charge, is formed using plasma enhanced atomic layer deposition (PEALD), the luminance characteristics of the light-emitting element ED may be improved. Accordingly, the display quality of the display device 10, which includes the light-emitting element ED having improved luminance characteristics, may also be improved.

Hereinafter, other embodiments related to the display device including the light-emitting element ED according to an embodiment will be described with reference to other drawings. In the following embodiments, a description of the same components as those of the above-described embodiment will be omitted or simplified, and differences will be described.

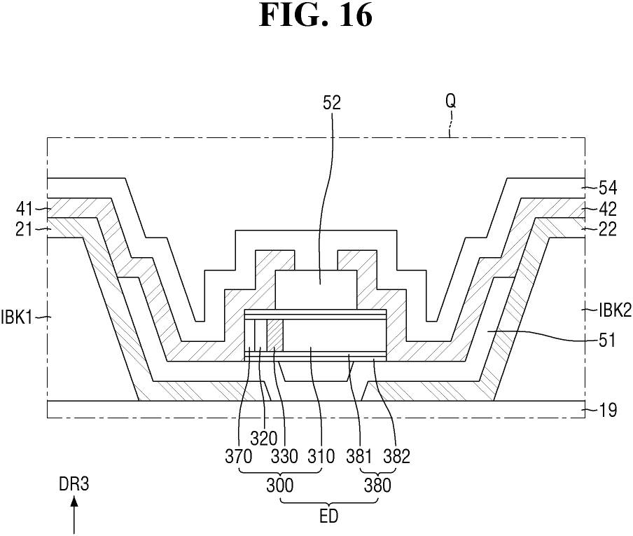

FIG. 16 is a schematic enlarged view illustrating another example of part Q of FIG. 3.

Referring to FIG. 16, the embodiment may be different from the embodiment of FIG. 6 in that the third insulating layer 53 is omitted.

Specifically, the first contact electrode 41 and the second contact electrode 42 may be directly disposed on the second insulating layer 52. The first contact electrode 41 and the second contact electrode 42 may be spaced apart from each other on the second insulating layer 52 to expose a part of the second insulating layer 52. The second insulating layer 52 exposed by the first contact electrode 41 and the second contact electrode 42 may contact the fourth insulating layer 54 in the exposed part.

In the embodiment, even in case that the third insulating layer 53 is omitted in the display device 10, the second insulating layer 52 may include an organic insulating material to perform the function of fixing the light-emitting element ED. The first contact electrode 41 and the second contact electrode 42 may be patterned and formed simultaneously by a single mask process. Accordingly, since no additional mask process is required to form the first contact electrode 41 and the second contact electrode 42, the process efficiency may be improved. The embodiment may be the same as the embodiment of FIG. 6 except that the third insulating layer 53 is omitted, and thus a redundant description will be omitted.

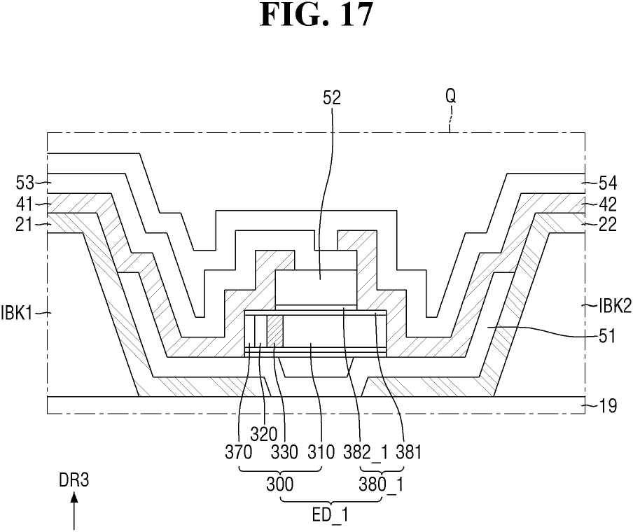

FIG. 17 is a schematic enlarged view illustrating still another example of part Q of FIG. 3.

Referring to FIG. 17, this embodiment may be different from the embodiment of FIG. 6 in that, in a light-emitting element ED_1 included in the display device 10, a second insulating layer (or insulating film) 382_1 of the insulating layer 380_1 of the light-emitting element ED_1 is partially removed, and the first and second contact electrodes 41 and 42 contact the first insulating layer 381 that is located at both ends of the light-emitting element ED.

Specifically, in the display device 10 according to this embodiment, at least a part of the second insulating layer 382_1 of the light-emitting element ED_1 may be removed so that the first insulating layer 381 located at both ends of the light-emitting element ED may be exposed in the third direction DR3. The first insulating layer 381, which is exposed by removing the second insulating layer 382_1, may be located at an upper part of the display device 10 in a cross-sectional view. The first and second contact electrodes 41 and 42 may contact the first insulating layer 381 exposed by the second insulating layer 382_1.

In the process of forming the second insulating layer 52 and/or the third insulating layer 53 during the manufacturing process of the display device 10, a part of the second insulating layer 382_1 of the light-emitting element ED_1 may also be partially etched. Specifically, a part of the second insulating layer 382_1 of the light-emitting element ED_1, which does not overlap the second insulating layer 52 and is exposed upward, may be etched. An etch selectivity (or an etch rate) of an etchant, which is used in the process for patterning the second insulating layer 52 or the third insulating layer 53, with respect to the second insulating layer 52 (or the third insulating layer 53) may be similar to or the same as an etch selectivity thereof with respect to the first insulating layer 381 of the light-emitting element ED_1. In order to prevent the first insulating layer 381 from being damaged in the process of patterning the second insulating layer 52, the second insulating layer 382_1 may be disposed to surround the first insulating layer 381 to protect it. Accordingly, the second insulating layer 382_1, which includes a material different from that of the first insulating layer 381, for example, a material having a different fixed charge, may protect the first insulating layer 381 from the etchant.

As shown in FIG. 17, the second insulating layer 382_1 may be partially etched in the process of patterning the second insulating layer 52. The first insulating layer 381 may be protected from the etchant by the second insulating layer 382_1 surrounding the outer circumferential surface of the first insulating layer 381 until the second insulating layer 382_1 is etched and completely removed. Accordingly, the first insulating layer 381 may be prevented from being damaged in the patterning process of the second insulating layer 52 and/or the third insulating layer 53, so that the first semiconductor layer 310, the second semiconductor layer 320 and the element active layer 330 of the light-emitting element ED_1 may be protected by the first insulating layer 381 surrounding them.

In this embodiment, since the display device 10 includes the light-emitting element ED_1 that includes the first insulating layer 381 having the first fixed charge described above, luminance deterioration of the light-emitting element ED_1 may be improved. Since the light-emitting element ED_1 includes the second insulating layer 382_1 that surrounds the first insulating layer 381 and has the second fixed charge different from the first fixed charge, the second insulating layer 382_1 may protect the first insulating layer 381 in the process of patterning the insulating layers of the display device 10. Therefore, even in case that the etch selectivity of the etchant, which is used in the process for patterning the second insulating layer 52, with respect to the second insulating layer 52 is similar to the etch selectivity thereof with respect to the first insulating layer 381, the second insulating layer 382_1 may protect the first insulating layer 381 in the manufacturing process of the display device 10. Accordingly, since the display device 10 includes the light-emitting element ED_1 having improved luminance efficiency, the light output efficiency of the display device 10 may be improved.

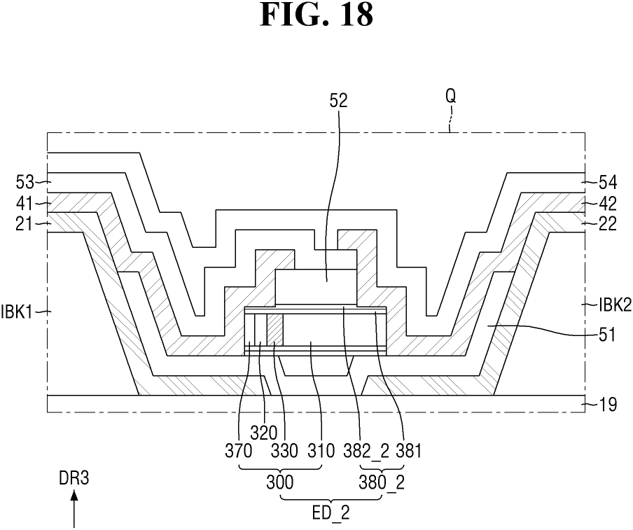

FIG. 18 is a schematic enlarged view illustrating still another example of part Q of FIG. 3.

Referring to FIG. 18, this embodiment may be different from the embodiment of FIG. 17 in that, in a light-emitting element ED_2 included in the display device 10, a second insulating layer 382_2 of the insulating layer 380_2 of the light-emitting element ED_2 may have a different thickness for each region.

As described above, in the process of forming the second insulating layer 52 and/or the third insulating layer 53 during the manufacturing process of the display device 10, the second insulating layer 382_2 of the light-emitting element ED_2 may also be partially etched. Accordingly, the second insulating layer 382_2 may have different thicknesses according to relative arrangements of adjacent members.

In this embodiment, an etch selectivity of an etchant, which is used in the process of patterning or forming the second insulating layer 52 or the third insulating layer 53, with respect to the second insulating layer 52 (or the third insulating layer 53) may be different from an etch selectivity thereof with respect to the second insulating layer 382_2. For example, the etch selectivity of the etchant with respect to the second insulating layer 52 (or the third insulating layer 53) may be greater than the etch selectivity thereof with respect to the second insulating layer 382_2. Accordingly, the second insulating layer 382_2 that does not overlap the second insulating layer 52 may not be completely removed, but may be partially etched to remain on the first insulating layer 381.

The thickness of the second insulating layer 382_2, which overlaps the second insulating layer 52, may be greater than the thickness of the second insulating layer 382_2 which does not overlap the second insulating layer 52. In the second insulating layer 382_2 facing upward in a cross-sectional view, since the second insulating layer 382_2 overlapping the second insulating layer 52 is not etched during the manufacturing process, the thickness of the insulating layer 382_2, which overlaps the second insulating layer 52, may be greater than the thickness of the second insulating layer 382_2 which does not overlap the second insulating layer 52.

In the second insulating layer 382_2 facing upward in a cross-sectional view, the second insulating layer 382_2, which does not overlap the second insulating layer 52, may contact the first contact electrode 41 and the second contact electrode 42. Accordingly, the thickness of the second insulating layer 382_2, which contacts the first and second contact electrodes 41 and 42, may be smaller than the thickness of the second insulating layer 382_2 which does not contact the first and second contact electrodes 41 and 42.

In this embodiment, similar to the display device 10 shown in FIG. 17, since the display device 10 includes the light-emitting element ED_2 that includes the first insulating layer 381 having the first fixed charge, it is possible to improve the luminance deterioration of the light-emitting element ED_2. Since the second insulating layer 382_2 of the light-emitting element ED_2 includes a material, which has the second fixed charge and has a low etch selectivity with respect to an etchant for forming the insulating layers of the display device 10, the first insulating layer 381 of the light-emitting element ED_2 may be more stably protected. Accordingly, since the display device 10 includes the light-emitting element ED having improved luminance efficiency and reliability, the light output efficiency of the display device 10 may be improved.

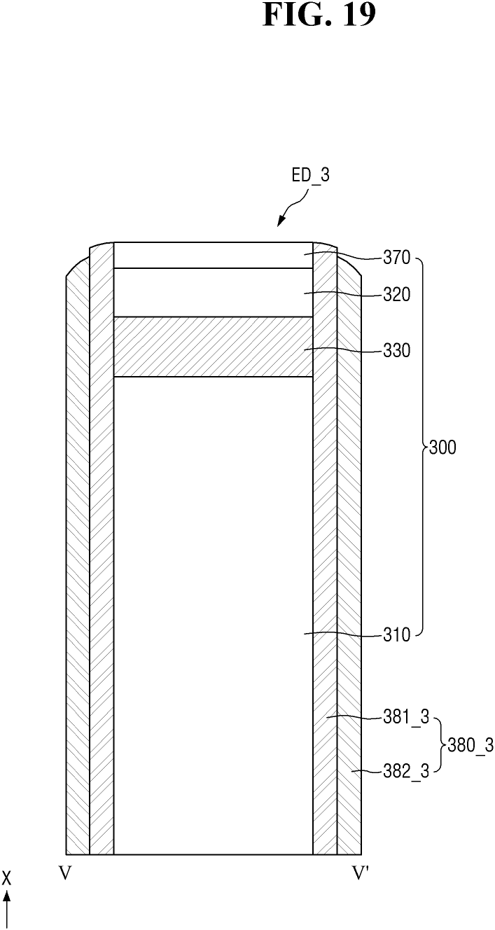

FIG. 19 is a schematic cross-sectional view of a light-emitting element according to another embodiment.

Referring to FIG. 19, in a light-emitting element ED_3 according to this embodiment, an insulating layer 380_3, which includes a first insulating layer 381_3 and a second insulating layer 382_3, may have a shape different from the shape of the insulating layer 380 of the light-emitting element ED of FIG. 5. Specifically, in the light-emitting element ED_3 according to this embodiment, the top surfaces or the upper cross sections of the first insulating layer 381_3 and the second insulating layer 382_3 may have a partially inclined shape. The first and second insulating layers 381_3 and 382_3 may include a region where the thickness of the light-emitting element ED_3 varies at an end of the light-emitting element ED_3.

The second insulating layer 382_3 may surround the outer circumferential surface of the first insulating layer 381_3, while exposing a part of the outer circumferential surface of the first insulating layer 381_3 at an end of the light-emitting element ED_3. The length of the first insulating layer 381_3 in the extension direction X of the light-emitting element ED_3 may be different from the length of the second insulating layer 382_3 in the extension direction X of the light-emitting element ED_3. For example, the length of the first insulating layer 381_3 in the extension direction X of the light-emitting element ED_3 may be greater than the length of the second insulating layer 382_3 in the extension direction X of the light-emitting element ED_3. Although FIG. 19 illustrates that the second insulating layer 382_3 surrounds the outer circumferential surface of the first insulating layer 381_3 while exposing a part of the outer circumferential surface of the first insulating layer 381_3, the disclosure is not limited thereto. For example, the top surfaces of the first and second insulating layers 381_3 and 382_3 may be formed to be rounded, but the top surfaces of the first and second insulating layers 381_3 and 382_3 may be aligned with each other, so that the second insulating layer 382_3 may be disposed to surround the outer circumferential surface of the first insulating layer 381_3 without exposing it.

The light-emitting element ED_3 according to this embodiment may be formed based on a difference in etch selectivity between the first insulating layer 381_3 and the second insulating layer 382_3 including different materials from each other in an etching process for forming the first insulating layer 381_3 and the second insulating layer 382_3.

Specifically, referring to FIGS. 12 and 13, an etchant, which is used in the etching process for forming the first insulating layer 381_3 and the second insulating layer 382_3 including different materials from each other, may have different etch selectivities with respect to the first insulating layer 381_3 and the second insulating layer 382_3. Accordingly, in case that the etch selectivity of the etchant with respect to the second insulating layer 382_3 is higher than the etch selectivity thereof with respect to the first insulating layer 381_3, the etch rate of the second insulating layer 382_3 may be higher than the etch rate of the first insulating layer 381_3. Therefore, the second insulating layer 382_3 may expose a part of the outer circumference surface of the first insulating layer 381_3.

In case that parts of the first and second insulating material layers 3810 and 3820 are removed through an etch-back process without a separate etch mask in a vertical etching process for forming the first and second insulating layers 381_3 and 382_3, since upper parts of the first and second insulating material layers 3810 and 3820 are exposed to the etchant for more time compared to lower parts of the first and second insulating material layers 3810 and 3820, the upper parts of the first and second insulating layers 381_3 and 382_3 located on the electrode layer 370 may be formed to be rounded as shown in FIG. 19.

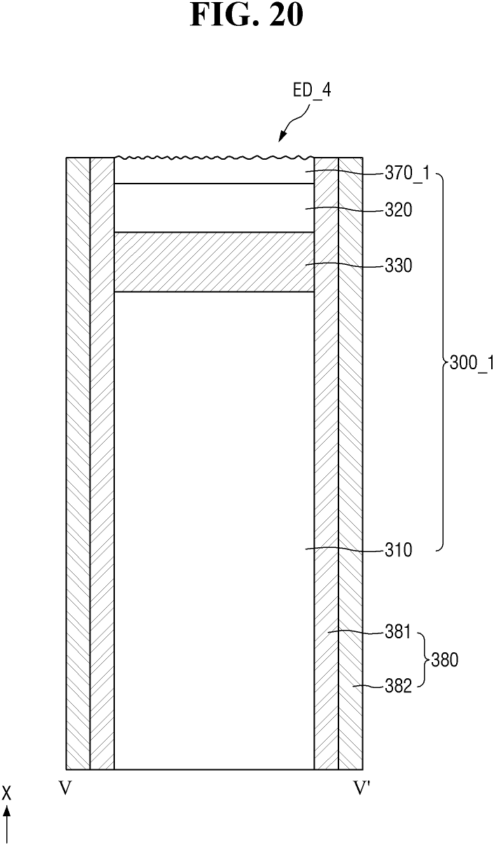

FIG. 20 is a schematic cross-sectional view of a light-emitting element according to still another embodiment.

Referring to FIG. 20, a light-emitting element core 300_1 of a light-emitting element ED_4 according to this embodiment may include an electrode layer 370_1 of which the top surface has surface irregularities. The surface irregularities (or a surface roughness) may be formed at the top surface (e.g., a surface toward a side of the extension direction X) of the electrode layer 370_1 of the light-emitting element ED_4 according to this embodiment. The surface irregularities may be randomly distributed. The surface irregularities may be formed in the etching process of removing parts of the first and second insulating material layers 3810 and 3820 to form the first and second insulating layers 381 and 382.

Specifically, referring to FIGS. 12 and 13, the etching process for forming the first and second insulating layers 381 and 382 may be performed as an etch-back process. The first and second insulating material layers 3810 and 3820, which are disposed on the top surface of the electrode layer 370 (see FIG. 12) of the core structure 300′ (see FIG. 12), may be etched by an etchant used in the etching process so that the top surface of the electrode layer 370_1 may be exposed. The exposed top surface of the electrode layer 370_1 may be partially etched by the etchant, thereby forming the light-emitting element ED_4 including the electrode layer 370_1 whose top surface has the surface irregularities as shown in FIG. 20.

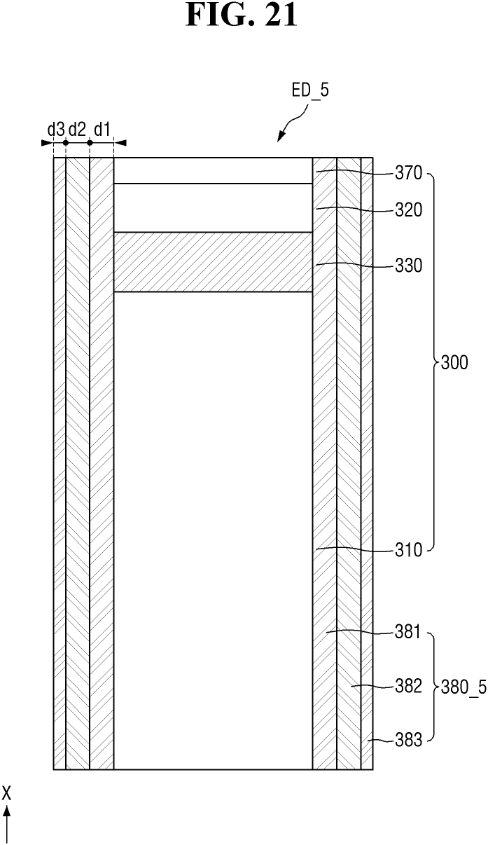

FIG. 21 is a schematic cross-sectional view of a light-emitting element according to still another embodiment.

Referring to FIG. 21, a light-emitting element ED_5 according to this embodiment may be different from the light-emitting element ED of FIG. 5 in that an insulating layer 380_5 includes triple insulating layers 381, 382, and 383. Specifically, the insulating layer 380_5 of the light-emitting element ED_5 may further include a third insulating layer 383 that surrounds the outer circumference surface of the second insulating layer 382. The third insulating layer 383 may include a material that has a third fixed charge different from the second fixed charge of the second insulating layer 382. For example, the fixed charges of the materials included in the second insulating layer 382 and the third insulating layer 383 may be different from each other. For example, the third insulating layer 383 may include at least one of the insulating materials listed as materials that the first insulating layer 381 may include.

In an embodiment, in case that the first insulating layer 381 includes silicon oxide (SiOₓ) having the first fixed charge and the second insulating layer 382 includes aluminum oxide (AlₓO_{y}) having the second fixed charge different from the first fixed charge, the third insulating layer 383 may include silicon oxide (SiOₓ) having the third fixed charge. However, the materials included in the first to third insulating layers 381, 382, and 383 are not limited thereto.

A thickness d3 of the third insulating layer 383 may be in a range of about 5 nm to about 100 nm, but is not limited thereto. Although FIG. 21 illustrates that the thickness d3 of the third insulating layer 383 is smaller than the respective thicknesses d1 and d2 of the first and second insulating layers 381 and 382, the relative magnitude relationship between the thickness of the third insulating layer 383 and the thicknesses of the first and second insulating layers 381 and 382 is not limited thereto. The thickness d3 of the third insulating layer 383 may be the same as the thickness d1 of the first insulating layer 381 or the thickness d2 of the second insulating layer 382, or may be greater than the thickness d1 of the first insulating layer 381 and/or the thickness d2 of the second insulating layer 382, within a range in which the luminance of the light-emitting element ED_5 is not decreased.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

1. A light-emitting element comprising:
a light-emitting element core comprising:
a first semiconductor layer;
a second semiconductor layer disposed on the first semiconductor layer; and
an element active layer disposed between the first semiconductor layer and the second semiconductor layer;
a first insulating layer disposed on a side surface of the light-emitting element core to surround the side surface of the light-emitting element core and having a first fixed charge; and
a second insulating layer surrounding an outer surface of the first insulating layer and containing a material having a second fixed charge different from the first fixed charge.

2. The light-emitting element of claim 1, wherein a polarity of the first fixed charge and a polarity of the second fixed charge are identical to each other.

3. The light-emitting element of claim 2, wherein
each of the first and second fixed charges is a positive fixed charge, and
a magnitude of the first fixed charge is smaller than a magnitude of the second fixed charge.

4. The light-emitting element of claim 2, wherein
each of the first and second fixed charges is a negative fixed charge, and
a magnitude of the first fixed charge is greater than a magnitude of the second fixed charge.

5. The light-emitting element of claim 1, wherein a polarity of the first fixed charge and a polarity of the second fixed charge are different from each other.

6. The light-emitting element of claim 5, wherein
the first fixed charge is a negative fixed charge, and
the second fixed charge is a positive fixed charge.

7. The light-emitting element of claim 1, wherein
the first insulating layer contains at least one of silicon oxide (SiOₓ), silicon nitride (SiNₓ), silicon oxynitride (SiOₓN_{y}), aluminum nitride (AlN), aluminum oxide (AlₓO_{y}), hafnium oxide (HfOₓ), and zirconium oxide (ZrOₓ), and
the second insulating layer contains at least one of silicon oxide (SiOₓ), silicon nitride (SiNₓ), silicon oxynitride (SiOₓN_{y}), aluminum nitride (AlN), and aluminum oxide (AlₓO_{y}).

8. The light-emitting element of claim 7, wherein
the first insulating layer contains silicon oxide (SiOₓ), and
the second insulating layer contains aluminum oxide (AlₓO_{y}).

9. The light-emitting element of claim 8, wherein
each of the first fixed charge of the silicon oxide (SiOₓ) and the second fixed charge of the aluminum oxide (AlₓO_{y}) is a positive fixed charge, and
the first fixed charge is smaller than the second fixed charge.

10. The light-emitting element of claim 8, wherein
the first fixed charge of the silicon oxide (SiOₓ) is a negative fixed charge, and
the second fixed charge of the aluminum oxide (AlₓO_{y}) is a positive fixed charge.

11. The light-emitting element of claim 1, wherein the first insulating layer is disposed directly on side surfaces of the first semiconductor layer, the second semiconductor layer, and the element active layer.

12. A display device comprising:
a first electrode disposed on a substrate;
a second electrode disposed on the substrate and spaced apart from the first electrode; and
a light-emitting element disposed on the substrate and having both ends disposed on the first electrode and the second electrode, respectively,
wherein the light-emitting element comprises:
a light-emitting element core comprising:
a first semiconductor layer;
a second semiconductor layer disposed on the first semiconductor layer; and
an element active layer disposed between the first semiconductor layer and the second semiconductor layer;
a first insulating layer disposed on a side surface of the light-emitting element core to surround the side surface of the light-emitting element core and having a first fixed charge; and
a second insulating layer surrounding an outer surface of the first insulating layer and containing a material having a second fixed charge different from the first fixed charge.

13. The display device of claim 12, wherein a polarity of the first fixed charge and a polarity of the second fixed charge are identical to each other.

14. The display device of claim 13, wherein
each of the first and second fixed charges is a positive fixed charge, and
a magnitude of the first fixed charge is smaller than a magnitude of the second fixed charge.

15. The display device of claim 13, wherein
each of the first and second fixed charges is a negative fixed charge, and
a magnitude of the first fixed charge is greater than a magnitude of the second fixed charge.

16. The display device of claim 12, wherein a polarity of the first fixed charge and a polarity of the second fixed charge are different from each other.

17. The display device of claim 16, wherein
the first fixed charge is a negative fixed charge, and
the second fixed charge is a positive fixed charge.

18. The display device of claim 12, further comprising:
a first insulating layer disposed on the light-emitting element to expose both ends of the light-emitting element;
a first contact electrode disposed on the first electrode and electrically contacting an end of the light-emitting element exposed by the first electrode and the first insulating layer; and
a second contact electrode disposed on the second electrode and electrically contacting another end of the light-emitting element exposed by the second electrode and the first insulating layer.

19. The display device of claim 18, wherein a thickness of the second insulating layer which is exposed by the first insulating layer is smaller than a thickness of the second insulating layer which is not exposed by the first insulating layer.

20. The display device of claim 19, wherein at both ends of the light-emitting element, the second insulating layer exposes a part of the first insulating layer.

21. A method of manufacturing a light-emitting element, comprising:
forming a core structure on one surface of a base substrate;
forming a first insulating material layer containing a material having a first fixed charge on an outer surface of the core structure using plasma atomic layer deposition (PEALD);
forming a second insulating material layer containing a material having a second fixed charge different from the first fixed charge on one surface of the first insulating material layer;
forming an element rod by partially removing the first insulating material layer and the second insulating material layer to expose a top surface of the core structure; and
separating the element rod from the base substrate.

22. The method of claim 21, wherein the forming of the first insulating material layer comprises:
providing a precursor onto the core structure;
providing a reactive gas onto the core structure; and
generating plasma of the reactive gas on the core structure.

23. The method of claim 22, wherein
the first insulating material layer contains silicon oxide (SiOₓ),
the second insulating material layer contains aluminum oxide (AlₓO_{y}),
the precursor comprises a silicon-containing precursor, and
the reactive gas contains an oxygen gas.

24. The method of claim 21, wherein the forming of the core structure comprises:
forming a first stacked structure comprising a first semiconductor material layer on the base substrate, an element active material layer on the first semiconductor material layer, and a second semiconductor material layer on the element active material layer; and
vertically etching the first stacked structure in a direction perpendicular to a top surface of the base substrate.
